(19) United States
(12) Patent Application Publication
(10) Pub. No.: US 2013/0180561 A1
(43) Pub. Date: Jul. 18, 2013

(54) NANOCOMPOSITES WITH HIGH THERMOELECTRIC PERFORMANCE AND METHODS

(71) Applicants: G. Jeffrey Snyder, Altadena, CA (US); Yanzhong Pei, Alhambra, CA (US)

(72) Inventors: G. Jeffrey Snyder, Altadena, CA (US); Yanzhong Pei, Alhambra, CA (US)

(73) Assignee: CALIFORNIA INSTITUTE OF TECHNOLOGY, Pasadena, CA (US)

(21) Appl. No.: 13/016,839

(22) Filed: Jan. 28, 2011

Related U.S. Application Data
(60) Provisional application No. 61/299,830, filed on Jan. 29, 2010.

(51) Int. Cl. H01L 35/16; H01L 35/28

(52) U.S. Cl. CPC H01L 35/16; H01L 35/28
USPC 136/203; 136/200; 252/500; 252/512; 252/519.4; 252/514; 136/201

(57) ABSTRACT

Disclosed herein include nanocomposites with improved thermoelectric performance. Also disclosed herein include methods of manufacturing and methods of using such nanocomposites.

### CROSS REFERENCE TO RELATED APPLICATION

This application claims priority under 35 U.S.C. §119(e) from U.S. Provisional Applications Ser. No. 61/299,830 filed Jan. 29, 2010, which is hereby incorporated by reference in its entirety.

### STATEMENT REGARDING FEDERALLY-SPONSORED RESEARCH

The U.S. Government has certain rights in this invention pursuant to Grant No. W911NF-08-C-0058 awarded by the Army.

### FIELD OF THE INVENTION

The instant disclosure relates to thermoelectric nanocomposites with high thermoelectric performance, methods of manufacturing thereof, and methods of using thereof.

### BACKGROUND

Thermoelectric applications, including both power generation utilizing the Seebeck effect and refrigeration utilizing Peltier effect, have attracted increasing interest worldwide in recent decade. For example, thermoelectric devices are being rapidly developed for waste heat recovery applications, particularly in automobiles, to produce electricity and reduce carbon emissions. The development of efficient thermoelectric devices for both space and terrestrial applications can benefit from availability of compositions with a high thermoelectric figure of merit (zT).

### SUMMARY OF THE INVENTION

Some embodiments of the disclosure relate to an article of manufacture comprising a matrix and nanoinclusions, wherein the nanoinclusions are uniformly dispersed in the matrix, and wherein the article of manufacture has a thermoelectric figure of merit (zT) of at least 1. The article of manufacture can have a thermoelectric figure of merit (zT) of at least 1.5. The matrix can include, for example, Pb, and the like. The matrix can include at least one composition selected from PbTe, PbSe, and the like. The nanoinclusions can include, for example, Ag, Cu, and the like. The nanoinclusions can include at least one composition selected from Ag₂Te, Ag₂Se, and the like. At least one dimension of the nanoinclusions is larger than 200 nanometers, or larger than 400 nanometers, or larger than 500 nanometers, or larger than 600 nanometers, or larger than 800 nanometers, or larger than 1 micrometers. The article of manufacture can further include a dopant. The dopant can include at least one composition selected from La and Na, and the like.

Some embodiments of the disclosure relate to a method of manufacturing an article including: heating a first material comprising at least a first element and a second material comprising at least a second element to form a mixture; cooling the mixture to precipitate nanoinclusions comprising the second element; and annealing the mixture. The first element of the first material can include Pb, and the like. The first material can further include at least one composition selected from Te, Se, and the like. The second element of the nanoinclusions can include Ag, Cu, and the like. The nanoinclusions can further include at least one composition selected from Te, Se, and the like. The method can further include repeating the cooling, and/or repeating the annealing. The method can further include doping the article with a dopant. The dopant can include at least one composition selected from La, Na, and the like.

Some embodiments of the instant disclosure are directed to a method of using an article of manufacture in a thermoelectric device, wherein the article of manufacture includes a matrix and nanoinclusions, wherein the nanoinclusions are uniformly dispersed in the matrix, and wherein the article of manufacture has a thermoelectric figure of merit (zT) of at least 1. In some embodiments, the method of using the article of manufacture includes applying a temperature gradient to the article of manufacture; and collecting electrical energy. In some embodiments, the method of using the article of manufacture includes applying electrical energy to the article of manufacture; and transferring heat from a first space at a first operation temperature to a second space at a second operation temperature, wherein the first operation temperature is lower than the second operation temperature.

### BRIEF DESCRIPTION OF THE DRAWINGS

FIG. 1: Estimated section of pseudo binary phase diagram of (PbTe)₁₋ₓ(Ag₂Te)ₓ system showing the strongly temperature dependent solubility of Ag₂Te in PbTe. The open circle at 773 K shows the experimental Ag solubility in PbTe. Starting with a homogenous melt at a composition of Ag5.5 (corresponding to x=5.5 mol. % in (PbTe)₁₋ₓ(Ag₂Te)ₓ)(point 1), the sample was quenched and then annealed within the single phase region (point 2) for homogenization. Phase separation was then achieved by annealing at 773 K (point 3). “L” stands for melt, and “ht1” stands for high temperature phase of Ag₂Te.

FIG. 2: (a) Back scattered electron images taken by field emission scanning electron microscopy for (PbTe)₁₋ₓ(Ag₂Te)ₓ nanocomposites (x=1.3 mol. %, 2.7 mol. %, 4.1 mol. %, 5.5 mol. %) showing the effect of increasing Ag₂Te content. The scale bars are 1 micrometer. (b) Extrapolation of the observed area fraction of precipitates (nanoinclusions) yields a phase boundary edge at x close to 1 mol. % for T=773 K. (c) XRD patterns shows PbTe and a small amount of Ag₂Te with monoclinic structure (arrows). In (c), the curves from the bottom to the top correspond to data for Ag5.5 (corresponding to x=5.5 mol. % in (PbTe)₁₋ₓ(Ag₂Te)ₓ), La1 (corresponding to z=1% in (PbLa_{z}Te_{1+z})_{0.945}(Ag₂Te)_{0.055}), La2 (corresponding to z=2% in (PbLa_{z}Te_{1+z})_{0.945}(Ag₂Te)_{0.055}), La3 (corresponding to z=3% in (PbLa_{z}Te_{1+z})_{0.945})(Ag₂Te)_{0.055}), and La4 (corresponding to z=4% in (PbLa_{z}Te_{1+z})_{0.945}(Ag₂Te)_{0.055}), respectively.

FIG. 3: (a) High temperature resistivity for the (PbTe)₁₋ₓ(Ag₂Te)ₓ nanocomposites. The decay in resistivity beginning at 400 K shows the behavior of an intrinsic semiconductor. Data for Ag1.3 (corresponding to x=1.3 mol. % in (PbTe)₁₋ₓ(Ag₂Te)ₓ), Ag2.7 (corresponding to x=2.7 mol. % in (PbTe)₁₋ₓ(Ag₂Te)ₓ), Ag4.1 (corresponding to x=4.1 mol. % in (PbTe)₁₋ₓ(Ag₂Te)ₓ), and Ag5.5 (corresponding to x=5.5 mol. % in (PbTe)₁₋ₓ(Ag₂Te)ₓ) are shown by the solid curve (see arrow) with the lowest peak resistivity, the dash-dotted curve, the solid curve (see arrow) with the highest peak resistivity, and the dotted curve, respectively. (b) The quick crossover of Hall coefficient (R_{H}) and Seebeck coefficient S provide additional evidences to the intrinsic conduction.

FIG. 4: Thermal conductivity as a function of temperature for (PbTe)₁₋ₓ(Ag₂Te)ₓ nanocomposites and n-type pure PbTe. The reduction of thermal conductivity increases with increasing concentration of the Ag₂Te phase. At high temperature, the bipolar thermal conductivity becomes a significant contribution to these intrinsically semiconducting materials (articles of manufacture). Data for Ag1.3 (corresponding to x=1.3 mol. % in (PbTe)₁₋ₓ(Ag₂Te)ₓ), Ag2.7 (corresponding to x=2.7 mol. % in (PbTe)₁₋ₓ(Ag₂Te)ₓ), Ag4.1 (corresponding to x=4.1 mol. % in (PbTe)₁₋ₓ(Ag₂Te)ₓ), and Ag5.5 (corresponding to x=5.5 mol. % in (PbTe)₁₋ₓ(Ag₂Te)ₓ) are shown by the solid curve with open circles, the solid curve with open squares, the solid curve with open triangles, and the solid curve with open pentagons, respectively; and data for n-type pure PbTe is shown by the solid curve with solid circles. The inset shows the agreement between experimental lattice thermal conductivity (κ_{L}^{Exp}) (open en circles) and predicted (calculated) lattice thermal conductivity (κ_{L}^{Cal}) (solid line) by the Debye-Calloway model for Ag1.3 at T<450 K.

FIG. 5: To assess the effect of Ag₂Te nanoparticles (nanoinclusions) on the PbTe thermal conductivity, the experimental results (open circles for 300 K and open squares for 400 K) are compared against alloy and effective medium models. Within the alloy limit (x close to 1 mol. %), a Debye-Callaway model for point defect scattering (mass and strain contrast) yields good agreement with experiment (region 1). The effective medium approximation (EMA) can describe the experimental results if the nanoparticles yield a nanocomposite and do not lead to enhanced scattering through interfacial effects. Two limits of the EMA are considered—(2, showed by a solid curve) zero and (3, showed by a dotted curve) infinite (Kapitza) interfacial resistance. Even with infinite interfacial resistance, this model significantly overestimates the lattice thermal conductivity and demonstrates Ag₂Te nanoparticles effectively reduce the phonon mean free path.

FIG. 6: (a) TEM image of Ag₂Te precipitates in La3-doped PbTe-Ag₂Te. The scale bar is 500 nanometers. (b) The electron diffraction pattern for the [101] PbTe zone axis indicates the precipitates are beta-Ag₂Te (β-Ag₂Te). Four distinct beta-Ag₂Te (β-Ag₂Te) variants are observed and labeled.

FIG. 7: (a) A 3D reconstruction for La3 specimen obtained via atom probe tomography indicates that no Ag₂Te features below 30 nanometers in size were observed. Each spot represents an individual atom shaded according to atom type. Only 10% of Pb and Te are shown for clarity. The scale bar is 10 nanometers. (b) Frequency histograms derived from atom probe tomography analysis show that the Ag and La fit the binomial curves as shown by black lines, and thus are homogeneously distributed in the PbTe matrix. The binomial curve (with the higher peak value) on the left is for Ag, and that on the right is for La.

FIG. 8: Temperature dependent Seebeck coefficient S (a), electrical resistivity ρ(b) and power factor (c) for La-doped (PbTe)_{0.945}(Ag2Te)_{0.055} nanocomposites shows behavior consistent with n-type degenerate semiconductors. The electrical resistivity shows a peak near 400 K, possibly due to the Ag₂Te beta (β)→alpha (α) transition. The inset of (a) shows the room temperature carrier density dependent Seebeck coefficient for the nanocomposites (open circles) and the comparison with the Pisarenko curve (solid curve) obtained for n-type bulk PbTe. Data for La1 (corresponding to z=1% in (PbLa_{z}Te_{1+z})_{0.945}(Ag₂Te)_{0.055}), La2 (corresponding to z=2% in (PbLa_{z}Te_{1+z})_{0.945}(Ag₂Te)_{0.055}), La3 (corresponding to z=3% in (PbLa_{z}Te_{1+z})_{0.945}(Ag₂Te)_{0.055}) and La4 (corresponding to z=4% in (PbLa_{z}Te_{1+z})_{0.945}(Ag₂Te)_{0.055}) are shown by the solid curve with open circles, the solid curve with open triangles pointing upward, the solid curve with open triangles pointing downward, and the solid curve with open stars, respectively.

FIG. 9: (a) Total thermal conductivity κ versus temperature. (b) The obtained lattice thermal conductivity κ_{L} of La-doped (PbTe)_{0.945}(Ag₂Te)_{0.055} is significantly lower than n-type PbTe and approaches the minimum value (dashed curve) at high temperature. (c) A comparison of lattice thermal conductivity across the PbTe nanocomposite efforts to date at 300 K (open columns) and near 650 K (solid columns). Literature values of lattice thermal conductivity κ_{L} were recalculated with Lorenz numbers obtained from the single parabolic band model described in the text. Again, the dashed curve shows the calculated minimal lattice thermal conductivity κ_{L}. In (a) or (b), data for La1 (corresponding to z=1% in (PbLa_{z}Te_{1+z})_{0.945}(Ag₂Te)_{0.055}), La2 (corresponding to z=2% in (PbLa_{z}Te_{1+z})_{0.945}(Ag2Te)_{0.055}), La3 (corresponding to z=3% in (PbLa_{z}Te_{1+z})_{0.945}(Ag₂Te)_{0.055}) and La4 (corresponding to z=4% in (PbLa_{z}Te_{1+z})_{0.945}(Ag₂Te)_{0.055}) are shown by the solid curve with open circles, the solid curve with open triangles pointing upward, the solid curve with open triangles pointing downward, and the solid curve with open stars, respectively; data for n-PbTe and Ag5.5 (corresponding to x=5.5 mol. % in (PbTe)₁₋ₓ(Ag₂Te)ₓ) are showed by the solid curve with solid circles and the solid curve with open pentagons, respectively. In (c), data shown in columns from left to right are for AgPb₁₈SbTe₂₀ (K. F. Hsu, S. Loo, F. Guo, W. Chen, J. S. Dyck, C. Uher, T. Hogan, E. K. Polychroniadis and M. G. Kanatzidis, Science, 303, 818, (2004)), NaPb₁₈SbTe₂₀ (A. Gueguen, P. F. P. Poudeu, C. Li, S. Moses, C. Uher, J. He, V. Dravid and K. M., Chem. Mater., 21, 1683, (2009)), Na_{0.95}Pb₁₈SbTe₂₂ (P. F. P. Poudeu, J. D'Angelo, J. L. Short, T. P. Hogan, and M. G. Kanatzidis, Angew. Chem. Int. Ed., 45, 3835, (2006)), AgPb₁₂Sn_{0.4}Sb_{0.4}Te₂₂ (J. Androulakis, K. F. Hsu, R. Pcionek, H. Kong, C. Uher, J. D'Angelo, A. Downey, T. Hogan and M. G. Kanatzidis, Adv. Mater., 18, 1170, (2006)), (Pb_{0.95}Sn_{0.05}Te)_{0.92}(PbS)_{0.08} (J. Androulakis, C. Lin, H. Kong, C. Uher, C. Wu, T. Hogan, B. A. Cook, T. Caillat, K. M. Paraskevopoulos and M. G. Kanatzidis, J. Am. Chem. Soc., 129, 9780, (2007)), Pb_{1.005}Sb_{0.02}Te (J. R. Sootsman, H. Kong, C. Uher and J. J. D. W. P. H. T. C. G. Kanatzidis, Angew. Chem. Int. Ed., 47, 8618, (2008)), and Ag_{0.8}Pb_{22.5}SbTe₂₀ (M. Zhou, J. Li and T. Kita, J. Am. Chem. Soc., 130, 4527, (2008)), each of which is hereby incorporated by reference. Data shown in the last column is for (PbLa_{0.02}Te_{1.02})0.945(Ag₂Te)_{0.0550}.

FIG. 10: Carrier concentration control of La-doped PbTe with Ag₂Te nano-precipitates (nanoinclusions) yields zT in excess of 1.5 at 775 K. Data for La1 (corresponding to z=1% in (PbLa_{z}Te_{1+z})_{0.945}(Ag₂Te)_{0.055}), La2 (corresponding to z=2% in (PbLa_{z}Te_{1+z})_{0.945}(Ag₂Te)_{0.055}), La3 (corresponding to z=3% in (PbLa_{z}Te_{1+z})_{0.945}(Ag₂Te)_{0.055}) and La4 (corresponding to z=4% in (PbLa_{z}Te_{1+z})_{0.945}(Ag₂Te)_{0.055}) are shown by the solid curve with open circles, the solid curve with open triangles pointing upward, the solid curve with open triangles pointing downward, and the solid curve with open stars, respectively.

FIG. 11: Typical nanostructure image of as cast PbTe:Na/Ag₂Te ingot. The short plates with a darker contrast indicate the Ag₂Te phase. The inset shows the nanostructure of hot pressed samples with small fraction of pores (black). The scale bar is 10 micrometers.

FIG. 12: (a) Room temperature Seebeck coefficient S versus Hall density p_{H} for PbTe:Na/Ag₂Te (open circles with error bars) with an overlaid Pisarenko plot for PbTe:Na (solid curve). The inset shows the schematic band structure at 300 K. (b) Temperature dependent Seebeck coefficient S along with PbTe:Na (the solid curve with annotation “PbTe:Na, 3.6e19”) and n-type PbTe:La/Ag2Te (La3, the solid curve with annotation “La3, 3.4e19). Complexity of valence band structure significantly increases the Seebeck coefficient S. Data for 2.5e19 (corresponding to doped samples with Hall density p_{H} of 2.5×10¹⁹ per cubic centimeter), 3.1e19 (corresponding to doped samples with Hall density p_{H} of 3.1×10¹⁹ per cubic centimeter), and 3.7e19 (corresponding to doped samples with Hall density p_{H} of 3.7×10¹⁹ per cubic centimeter) are shown by the solid curve with open squares, the solid curve with open circles, and the solid curve with open stars, respectively.

FIG. 13: Temperature dependent electrical conductivity a for PbTe:Na/Ag₂Te and PbTe:Na (the solid curve with annotation “PbTe:Na, 3.6e19”). Ag₂Te nanoinclusions strongly scatter the carriers thereby reducing the Hall mobility μ_{H}, particularly at low temperatures as shown in the inset. Data for 2.5e19 (corresponding to doped samples with Hall density p_{H} of 2.5×10¹⁹ per cubic centimeter), 3.1e19 (corresponding to doped samples with Hall density p_{H} of 3.1×10¹⁹ per cubic centimeter), and 3.7e19 (corresponding to doped samples with Hall density p_{H} of 3.7×10¹⁹ per cubic centimeter) are shown by the solid curve with open squares, the solid curve with open circles, and the solid curve with open stars, respectively.

FIG. 14: Temperature dependent thermal conductivity κ (solid curves with open circles for 3.1e19 or open stars for 3.7e19) and its lattice component κ_{L} (dashed curves with solid circles for 3.1e19 or solid stars for 3.7e19) for PbTe:Na/Ag₂Te compared to temperature dependent thermal conductivity κ (the solid curve with annotation “PbTe:Na”) and its lattice component κ_{L} (the dashed curve with annotation “PbTe:Na”) for PbTe:Na. Ag₂Te nanoinclusions effectively scatter phonons thus reducing the lattice thermal conductivity κ_{L} to close to 0.5 W/m-K at T>600 K. “3.1e19” corresponds to doped samples with Hall density p_{H} of 3.1×10¹⁹ per cubic centimeter; and “3.7e19” corresponds to doped samples with Hall density PH of 3.7×10¹⁹ per cubic centimeter.

FIG. 15: (a) Temperature dependent thermoelectric figure of merit zT for PbTe:Na/Ag₂Te, PbTe:Na and PbTe:La/Ag₂Te (La3, the solid curve with annotation “La3, 3.4e19”). The improvement in thermoelectric figure of merit zT is attributed to the reduction of the lattice thermal conductivity κ_{L} in PbTe:Na (dashed curve). Data for 2.5e19 (corresponding to doped samples with Hall density p_{H} of 2.5×10¹⁹ per cubic centimeter), 3.1e19 (corresponding to doped samples with Hall density p_{H} of 3.1×10¹⁹ per cubic centimeter), and 3.7e19 (corresponding to doped samples with Hall density p_{H} of 3.7×10¹⁹ per cubic centimeter) are shown by the solid curve with open squares, the solid curve with open circles, and the solid curve with open stars, respectively. (b) Comparison of the maximum efficiency (left column of each pair) and average thermoelectric figure of merit zT (right column of each pair) at 300 to 750 K for PbTe:Na/Ag₂Te (the third pair of columns), PbTe:Na (the second pair of columns) and PbTe:La/Ag₂Te (the first pair of columns) with room temperature Hall density p_{H} of close to 3.5e19 per cubic centimeter. Data for the measured zT on PbTe:Na is shown by the solid curve; and data for the calculated zT for PbTe:Na (assuming a lattice thermal conductivity of PbTe:Na/Ag₂Te nanocomposites) is shown by the dashed curve. There is roughly a 100-40% enhancement in the average thermoelectric figure of merit zT due to the band structure complexity and nanostructuring.

### DETAILED DESCRIPTION

Thermoelectric (TE) applications have attracted increasing interest worldwide in the last decade as a means to combat the ever growing rate of energy consumption. The two main applications for thermoelectric materials are power generation, which utilizes the Seebeck effect, and solid state cooling, which has its roots in the Peltier effect. Recently, however, power generation has been a prime interest to the automotive industry as a sustainable and emission free waste heat recovery process. Discussion about this can be found at, for example, L. E. Bell, Science (2008), 321, 1457, which is hereby incorporated by reference. The effectiveness of this process is restricted by the overall efficiency of the thermoelectric materials.

A common figure of merit for a thermoelectric material, denoted by z, is defined as z=S²σ/(κ_{E}+κ_{L}), where S is the Seebeck coefficient, σ is the electrical conductivity, and κ_{E} and κ_{L} the electronic (or carrier) component and phonon (or lattice) component of the thermal conductivity, respectively. The Seebeck coefficient S for a thermoelectric material is the voltage difference per degree Kelvin. The electrical conductivity a is inverse of the electrical resistivity ρ. The figure of merit z has the units of reciprocal Kelvin. Another figure of merit, which is referred to as thermoelectric figure of merit, can be defined as zT, where T is the absolute temperature in Kelvin, so that zT is a dimensionless quantity.

Materials investigated and optimized over the past 50 years have been conventional, simple semiconductors. Examples include alloys of bismuth telluride, lead telluride, and silicon germanium, with the best of these exhibiting thermoelectric figure of merit zT values of no greater than 1. Recently, this thermoelectric figure of merit zT barrier has been broken, so that thermoelectric figure of merit zT>2 has been achieved in thin film superlattices or quantum well materials with feature sizes of several to tens of nanometers. See, for example, Caylor, J. C., Coonley, K., Stuart, J., Colpitts, T., and Venkatasubramanian, R. Applied Physics Letters (2005), 87, 23105; Venkatasubramanian, R.; Siivola, E.; Colpitts, T.; O'Quinn, B. Nature (2001), 413, 597-602; and Harman, T. C.; Taylor, P. J.; Walsh, M. P.; LaForge, B. E. Science (2003), 297, 2229-2232, each of which is hereby incorporated by reference. The first significant result has been that of Venkatasubramanian (2001) who demonstrated thermoelectric figure of merit zT=2.4 using Bi₂Te₃—Sb₂Te₃ quantum well superlattices with 6-nanometer periodicity. Harman and coworkers prepared quantum dot superlattices in the PbTe—PbSeTe system (described as PbSe nanodots embedded in a PbTe matrix) and demonstrated thermoelectric figure of merit zT values of 1.6.

Despite the high thermoelectric figure of merit zT of such thermoelectrics, the performance of devices utilizing superlattice materials has not yet surpassed the performance of bulk Bi₂Te₃ based devices. This is due to the small size of the thermoelectric elements that currently are achieved from ‘top-down’ fabrication methods, which imply a large, relative contribution of electrical and thermal contact resistances.

Because S, σ (or ρ), and κ_{E} have an intimate relationship with the carrier density, strategies of optimizing the carrier density and minimizing the independent parameter κ_{L} can be effective route to improve zT. More discussion can be found at, for example, A. F. Ioffe, Semiconductor thermoelements, and Thermoelectric cooling, Infosearch, London, (1957); and G. J. Snyder, E. S. Toberer, Nat Mater (2008), 7, 105, each of which is hereby incorporated by reference.

Two recently proposed mechanisms have shown to enable a significant enhancement of the Seebeck coefficient, and therefore an improvement in zT, by a distortion in the density of states and also carrier pocket engineering. Merely by way of example, due to the complex valence band structure of PbTe, heavily doped p-type PbTe:Na, which does not have resonant states, has been found to have similarly high thermoelectric performance to that of a material that does have resonant states, namely PbTe:Tl. However, this influence on the valence band structure is an electronic effect, indicating the possibility in further enhancing zT for PbTe:Na by reducing the lattice thermal conductivity. See, for example, T. Koga, X. Sun, S. Cronin, M. Dresselhaus, Appl Phys Lett (1998), 73, 2950; O. Rabina, Y. Lin, M. Dresselhaus, Appl Phys Lett (2001), 79, 81; M. S. Dresselhaus, G. Chen, M. Y. Tang, R. G. Yang, H. Lee, D. Z. Wang, Z. F. Ren, J. P. Fleurial, P. Gogna, Adv Mater (2007), 19, 1043; and J. Heremans, V. Jovovic, E. Toberer, A. Saramat, K. Kurosaki, A. Charoenphakdee, G. J. Snyder, Science (2008), 321, 554, each of which is hereby incorporated by reference.

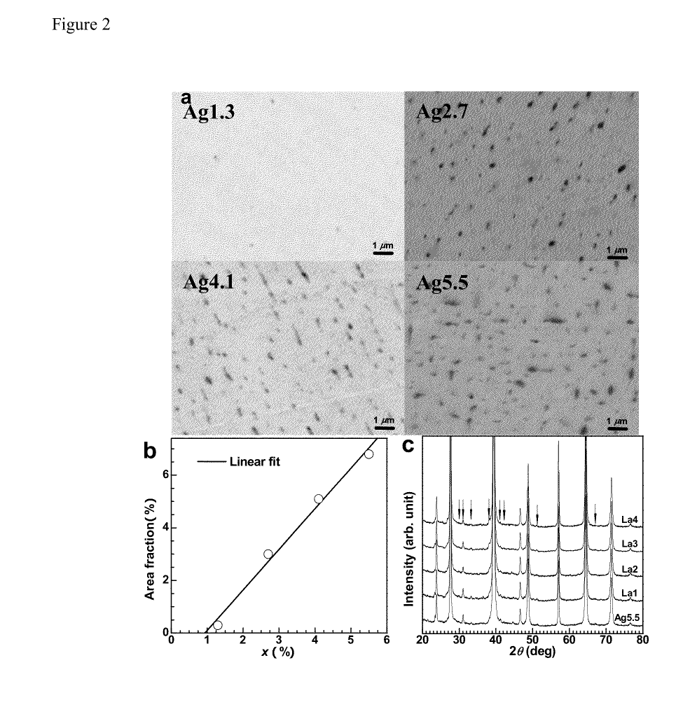

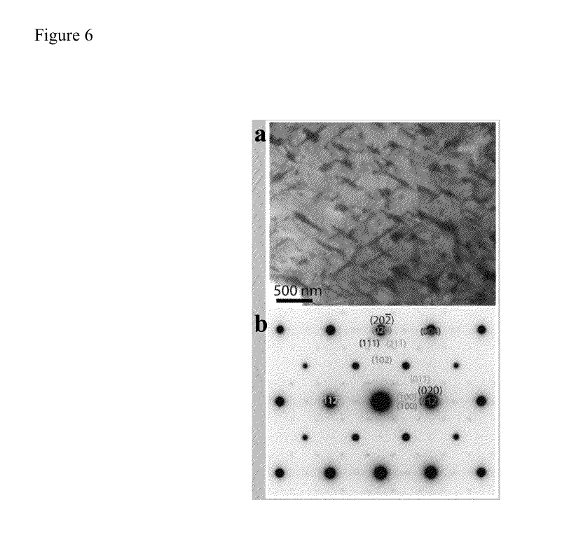

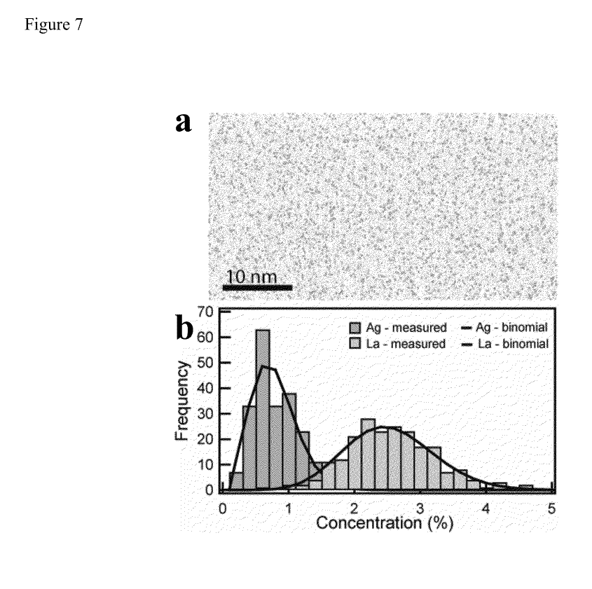

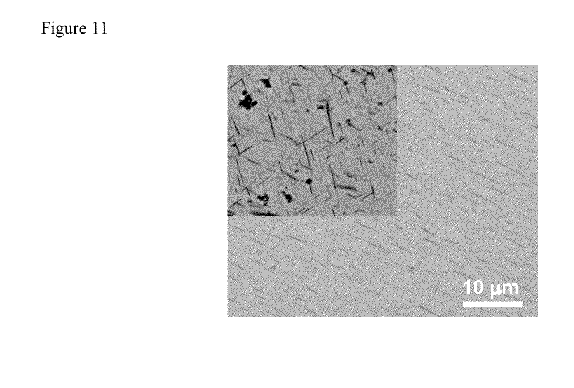

Unless otherwise stated, a nanocomposite and an article of manufacture are used interchangeably in the instant disclosure. In some portions of the disclosure, a nanocomposite or article of manufacture is also referred to as a sample. Exemplary embodiments of nanocomposites or articles of manufacture are illustrated in, for example, FIG. 2, FIG. 6, FIG. 7, and FIG. 11, and the description thereof. It is understood that these are for illustration purposes only, and not intended to limit the scope of the disclosure.

As used herein, nanoinclusions refer to the inclusions in the matrix of a nanocomposite (or article of manufacture) that has a different composition than the matrix. The size of a nanoinclusion can be at a nanometer scale or a micrometer scale. Merely by way of example, a nanoinclusion has at least one dimension that is larger than 1 micrometer.

Unless otherwise stated, carrier density and carrier concentration are used interchangeably in the instant disclosure.

In some embodiments, the numbers expressing quantities of ingredients, properties such as molecular weight, reaction conditions, and so forth, used to describe and claim certain embodiments of the application are to be understood as being modified in some instances by the term “about.” Accordingly, in some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the application are approximations, the numerical values set forth in the specific examples are reported as precisely as practicable.

Strategies to synthesize bulk nanostructured materials for thermoelectrics are inspired by classic metallurgical approaches. Several themes are used in these syntheses of the instant disclosure: (a) solid state partitioning on cooling due to the crossing from a single to two-phase region, (b) formation and subsequent decomposition of a metastable phase, and (c) solidification from the melt. One advantage of these transformations is that the microstructural or nanostructural length scales can be controlled by diffusion, and thus varying processing parameters allows a wide range of microstructures or nanostructures to be obtained. This is described in more detail elsewhere in the instant disclosure. More discussion can be found at, for example, T. Ikeda, L. A. Collins, V. A. Ravi, F. S. Gascoin, S. M. Haile and G. J. Snyder, Chem. Mater., 19, 763-767, (2007); T. Ikeda, S. M. Haile, V. A. Ravi, H. Azizgolshani, F. Gascoin and G. J. Snyder, Acta Materialia, 55, 1227-1239, (2007); T. Ikeda, V. A. Ravi and G. J. Snyder, Acta Materialia, 57, 666-672, (2009); and D. L. Medlin and G. J. Snyder, Current Opinion In Colloid & Interface Science, 14, 226, (2009), each of which is incorporated by reference.

Some embodiments of the instant disclosure are directed to an article of manufacture comprising a matrix and nanoinclusions, wherein the nanoinclusions are uniformly dispersed in the matrix, and wherein the article of manufacture has a thermoelectric figure of merit zT of at least 1. The nanoinclusions can scatter phonons effectively, leading to a low lattice thermal conductivity κ_{L}. The article of manufacture can include at least one dopant to optimize the carrier density. The article of manufacture has an improved thermoelectric figure of merit zT.

In some embodiments, the matrix includes at least one composition selected from lead (Pb), selenium (Se), tellurium (Te), antimony (Sb), germanium (Ge), silicon (Si), tin (Sn), bismuth (Bi), arsenic (As), indium (In), thallium (Tl), and the like, or an alloy thereof. In some exemplary embodiments, the matrix includes PbTe, or PbSe. The advantages of PbSe for thermoelectric application include, but not limited to, low cost and tolerance to high temperature. In some exemplary embodiments, the matrix includes PbSeₓTe₁₋ₓ, wherein x represents the fraction of PbSe in the alloy of PbTe and PbSe, and can be from (and including) 0 to (and including) 1. In some embodiments, the matrix includes HgCdTe, PbS, InAs, InSb, Cd₃As₂, Bi₂Te₃, SnTe, and the like. In some embodiments, the matrix includes a narrow-gap semiconductor. In some embodiments, the matrix has nanoscale features of less than 1 micrometer, or less than 800 nanometers, or less than 600 nanometers, or less than 400 nanometers, or less than 200 nanometers, or less than 100 nanometers, or less than 80 nanometers, or less than 60 nanometers, or less than 40 nanometers, or less than 20 nanometers.

In some embodiments, the nanoinclusions are not isostructural to the matrix. For example, the dimension of the nanoinclusions is larger than the nanoscale features of the matrix so that they enhance the phonon scattering, which can reduce the lattice thermal conductivity κ_{L}. In some embodiments, the nanoinclusions have dimensions (along its minor axis if the shape is not isometric) of larger than 20 nanometers, or larger than 40 nanometers, or larger than 50 nanometers, or larger than 60 nanometers, or larger than 80 nanometers, or larger than 100 nanometers, or larger than 120 nanometers, or larger than 150 nanometers, or larger than 180 nanometers, or larger than 200 nanometers, or larger than 250 nanometers, or larger than 300 nanometers, or larger than 400 nanometers, or larger than 500 nanometers. In some embodiments, the nanoinclusions have dimensions (along its major axis if the shape is not isometric) of less than 1 micrometer, or less than 800 nanometers, or less than 600 nanometer, or less than 500 nanometers, or less than 400 nanometers, or less than 300 nanometers, or less than 250 nanometers, or less than 200 nanometers, or less than 150 nanometers, or less than 100 nanometers, or less than 80 nanometers, or less than 60 nanometers, or less than 50 nanometers. In some embodiments, the article includes some smaller nanoinclusions in addition to large nanoinclusions. Merely by way of example, an article includes a matrix with nanoscale features of close to or less than 20 nanometers, large nanoinclusions of 50 nanometers-200 nanometers and small nanoinclusions of less than 50 nanometers. A nanoinclusion can have a shape roughly of a sphere, a rod, a cylinder, an ellipsoid, a plate, and the like. As used herein, “roughly” indicates that the shape of a nanoinclusion may not be perfect. In some embodiments, the nanoinclusions in the matrix have a relatively large scale with at least one dimension that is larger than 200 nanometers, or larger than 400 nanometers, or larger than 500 nanometers, or larger than 600 nanometers, or larger than 800 nanometers. In some embodiments, at least one dimension of the nanoinclusions in the matrix is larger than 1 micrometer. The nanoinclusions with relatively large scale are effective in enhancing phonon scattering, and thereby lowering lattice thermal conductivity κ_{L} and improving the thermoelectric performance of the article. In some embodiments, the nanoinclusions are dispersed in the matrix uniformly. In some embodiments, the nanoinclusions are dispersed in the matrix at some other pattern. In some embodiments, the nanoinclusions are dispersed in the matrix randomly. In some embodiments, the average number density of the nanoinclusions in a matrix is from 1 per cubic micrometer to about 200 per cubic micrometer, or from 5 per cubic micrometer to 150 per cubic micrometer, or from 10 per cubic micrometer to 120 per cubic micrometer, or from 20 per cubic micrometer to 100 per cubic micrometer, or from 30 per cubic micrometer to 80 per cubic micrometer, or from 40 per cubic micrometer to 60 per cubic micrometer. In some embodiments, the average number density of the nanoinclusions in a matrix is from 1 per cubic micrometer to about 10 per cubic micrometer, or from 10 per cubic micrometer to about 20 per cubic micrometer, or from 20 per cubic micrometer to about 40 per cubic micrometer, or from 40 per cubic micrometer to about 60 per cubic micrometer, or from 60 per cubic micrometer to about 80 per cubic micrometer, or from 80 per cubic micrometer to about 100 per cubic micrometer, or higher than 100 per cubic micrometer. In some embodiments, the spacing between nanoinclusions is from 10 nanometers to 10 micrometers, or from 50 nanometers to 5 micrometers, or from 100 nanometers to 1 micrometer, or from 150 nanometers to 500 nanometers, or from 200 nanometers to 300 nanometers. In some embodiments, the spacing between nanoinclusions is from 10 nanometers to 50 nanometers, or from 50 nanometers to 100 nanometers, or from 100 nanometers to 200 nanometers, or from 200 nanometers to 400 nanometers, or from 400 nanometers to 600 nanometers, or from 600 nanometers to 800 nanometers, or from 800 nanometers to 1000 nanometers, or larger than 1000 nanometers. In some embodiments, the nanoinclusions (e.g., the size, shape, average number density) do not introduce considerable electronic doping effect to the matrix, and do not significantly affect the carrier density of the matrix. This way, the effect of the nanoinclusions on the improved thermoelectric figure of merit is due primarily to the reduced lattice thermal conductivity κ_{L}. The microstructural or nanostructural parameters of the nanoinclusions, including the size, spacing, and the like, can be controlled or adjusted by, for example, adjusting the conditions under which the article is formed. Merely by way of example, annealing time and temperature is proportional to the size growth of the nanoinclusions.

In some embodiments, the nanoinclusions introduce electronic doping effect to the matrix such that, in addition to the reduced lattice thermal conductivity κ_{L}, the carrier density is improved, and the thermoelectric figure of merit is improved. The nanoinclusions can include, for example, silver (Ag), copper (Cu) and the like, or an alloy thereof. Merely by way of example, the nanoinclusions include an alloy of silver (Ag) and a constituent composition of the matrix, e.g., selenium (Se), tellurium (Te), and the like.

Thermoelectric performance of an article of manufacture for thermoelectric application can be improved by careful control of carrier concentrations through doping. In some embodiments, the article of manufacture is doped with at least one dopant. The article can be doped with an n-type dopant, or a p-type dopant. Effective electron donor dopants (n-type dopants) include, for example, lanthanum (La), thulium (Tm), indium (In), iodine (I), and the like. Effective electron acceptor dopants (p-type dopants) include, for example, sodium (Na), potassium (K), thallium (Tl), and the like. Merely by way of example, thallium (Tl) is a good choice for p-type dopant as it can enhance zT to 1.5 in bulk PbTe by distortion of the electronic density of states. In some embodiments, lanthanum (La)-doping effectively leads to conducting behavior dominated by degenerate charge carriers. The doping concentration can be optimized for different articles including different constituent compositions. In some embodiments, an extrinsic dopant concentration is at least 0.01 at. %, or at least 0.05 at. %, or at least 0.08 at. %, or at least 0.1 at. %, or at least 0.2 at. %, or at least 0.5 at. %, or at least 0.6 at. %, or at least 0.8 at. %, or at least 1 at. %, or at least 1.2 at. %, or at least 1.5 at. %, or at least 1.8 at. %, or at least 2 at. %, or at least 2.2 at. %, or at least 2.5 at. %, or at least 2.8 at. %, or at least 3 at. %. In some embodiments, an extrinsic dopant concentration is lower than 10 at. %, or lower than 8 at. %, or lower than 6 at. %, or lower than 5 at. %, or lower than 4 at. %, or lower than 3 at. %, or lower than 2 at. %, or lower than 1 at. %. In some embodiments, carrier density is at least 10¹⁸ per cubic centimeter, or at least 2×10¹⁸ per cubic centimeter, or at least 4×10¹⁸ per cubic centimeter, or at least 5×10¹⁸ per cubic centimeter, or at least 6×10¹⁸ per cubic centimeter, or at least 8×10¹⁸ per cubic centimeter, or at least 10¹⁹ per cubic centimeter, or at least 2×10¹⁹ per cubic centimeter, or at least 4×10¹⁹ per cubic centimeter, or at least 5×10¹⁹ per cubic centimeter, or at least 6×10¹⁹ per cubic centimeter, or at least 8×10¹⁹ per cubic centimeter, or at least 10²⁰ per cubic centimeter, or at least 2×10²⁰ per cubic centimeter, or at least 4×10²⁰ per cubic centimeter, or at least 5×10²⁰ per cubic centimeter. Merely by way of example, an optimal carrier density is 10¹⁹-10²⁰ per cubic centimeter.

The following description regarding some exemplary embodiments of the article of manufacture is for illustration purposes, and is not intended to limit the scope of the disclosure. In some exemplary embodiments, the article of manufacture includes a matrix including PbTe and nanoinclusions including Ag₂Te. The matrix has small nanoscale features of less than 20 nanometers. The nanoinclusions are of relatively larger scale. The nanoinclusions are plate-like. Some nanoinclusions have long dimensions of 100-200 nanometers and short dimensions of 50-100 nanometers. Some nanoinclusions have long dimensions of larger than 200 nanometers, some are larger than 1 micrometer. The article of manufacture has improved thermoelectric figure of merit at room temperature and at a temperature higher than room temperature. With the nanoinclusions of Ag₂Te in PbTe, no overwhelming electronic doping effects are found: above 400 K the articles show intrinsic semiconductor behavior and the transition temperature from extrinsic to intrinsic conduction is independent of Ag content. The article can be doped to further improve thermoelectric transport with, for example, lanthanum (La), sodium (Na), and the like.

In some embodiments, an article of manufacture as disclosed herein has improved thermoelectric performance. The article of manufacture can have an improved thermoelectric figure or merit, and/or improved theoretically available power generation efficiency (ηₘₐₓ). This can be due to the band structure complexity and nanostructured effects. As is demonstrated herein in PbTe:Na/Ag₂Te, a peak thermoelectric figure of merit zT higher than 1.5 and significant enhancements of average thermoelectric figure of merit zT/thermoelectric efficiency can be realized. Further optimizing the combination of carrier density and nanostructure control can result in an even higher thermoelectric performance. PbTe:Na/Ag₂Te and similar PbTe materials are described herein merely for the purpose of illustration. This is not intended to limit the scope of the disclosure. In some embodiments, an article of manufacture including PbSe or a similar composition has improved thermoelectric performance due to the band structure complexity and nanostructured effects; further optimizing the combination of carrier density and nanostructure control results in an even higher thermoelectric performance.

Some embodiments of the instant disclosure are directed to a method of manufacturing an article including: heating a first material including at least a first element and a second material including at least a second element to form a mixture; cooling the mixture to precipitate nanoinclusions including the second element; and annealing the mixture.

In some embodiment, the method of manufacturing an article includes heating the first material including at least a first element and the second material including at least a second element to form a mixture. The heating melts the first material and the second material to form a homogeneous mixture or melt at a first temperature. The first temperature is higher, at a first temperature different, than the higher of the melting temperature of the first material and that of the second material. The first temperature difference can be at least 1 K, or at least 2 K, or at least 5 K, or at least 8 K, or at least 10 K, or at least 12 K, or at least 15 K, or at least 20 K, or at least 25 K, or at least 30 K, or at least 35 K, or at least 40 K, or at least 45 K, or at least 50 K. The heating can be achieved at an essentially constant temperate increase rate. The temperate increase rate can be at least 10 K/hour, or at least 50 K/hour, or at least 80 K/hour, or at least 100 K/hour, or at least 120 K/hour, or at least 150 K/hour, or at least 180 K/hour, or at least 200 K/hour, or at least 220 K/hour, or at least 250 K/hour, or at least 280 K/hour, or at least 300 K/hour, or at least 320 K/hour, or at least 350 K/hour, or at least 380 K/hour, or at least 400 K/hour, or at least 420 K/hour, or at least 450 K/hour, or at least 480 K/hour, or at least 500 K/hour, or at least 520 K/hour, or at least 550 K/hour, or at least 580 K/hour, or at least 600 K/hour, or at least 650 K/hour, or at least 700 K/hour, or at least 750 K/hour, or at least 800 K/hour. The heating can be achieved at a variable temperate increase rate. The essentially constant or variable temperate increase rate can be achieved by controlling, for example, the rate of energy input to the heating process. In some embodiments, the heating is achieved in a closed chamber. In some embodiments, the heating is achieved at or close to the atmospheric pressure. In some embodiments, the heating is achieved under vacuum. Merely by way of example, the chamber pressure is of 10⁻⁵ torr or less. In some embodiments, the heating is achieved at a chamber pressure that is higher than the atmospheric pressure. In some embodiments, the heating lasts at least 0.1 hours, or at least 0.5 hours, or at least 1 hour, or at least 1.5 hours, or at least 2 hours, or at least 2.5 hours, or at least 3 hours, or at least 4 hours, or at least 5 hours, or at least 6 hours, or at least 7 hours, or at least 8 hours, or at least 10 hours, or at least 12 hours, or at least 15 hours, or at least 20 hours, or at least 24 hours, or at least 30 hours, or at least 36 hours, or at least 42 hours, or at least 48 hours.

In some embodiments, the first material includes a first element that forms a matrix of an article of manufacture. The first material can include more constituent compositions of the matrix. The matrix includes at least one composition selected from lead (Pb), selenium (Se), tellurium (Te), antimony (Sb), germanium (Ge), silicon (Si), tin (Sn), bismuth (Bi), arsenic (As), indium (In), thallium (Tl), and the like, or an alloy thereof. In some exemplary embodiments, the matrix includes PbTe, or PbSe. In some exemplary embodiments, the matrix includes PbSeₓTe₁₋ₓ, wherein x represents the fraction of PbSe in the alloy of PbTe and PbSe, and can be from (and including) 0 to (and including) 1.

In some embodiments, the second material includes a second element that forms nanoinclusions of an article of manufacture. Merely by way of example, the second element includes silver (Ag) or copper (Cu). The second material can include more constituent compositions of the matrix or the nanoinclusions of an article of manufacture.

In some embodiments, the method of manufacturing an article includes cooling the mixture to precipitate nanoinclusions including the second element. The cooling is performed by contacting a coolant directly or indirectly with the mixture so that the mixture is at a second temperature. By cooling, the second element of the second material precipitates from the matrix to form nanoinclusions. The nanoinclusions include at least the second element. The nanoinclusions can further include other constituent compositions of the article of manufacture. Merely by way of example, the nanoinclusions include an alloy of the second element. As used herein, “indirectly” means that the coolant and the mixture are separated from each other by a partition, e.g., the wall of a container holding the mixture. The coolant can be at least one medium selected from a liquid (e.g., oil, water, and the like), and a gas (air, an inert gas, and the like). Merely by way of example, the cooling is achieved by cold water quenching. The second temperature is lower, at a second temperature difference, than the melting temperature of at least one of the first material and the second material. The second temperature difference can be at least 1 K, or at least 2 K, or at least 5 K, or at least 8 K, or at least 10 K, or at least 12 K, or at least 15 K, or at least 20 K, or at least 25 K, or at least 30 K, or at least 35 K, or at least 40 K, or at least 45 K, or at least 50 K, or at least 80 K, or at least 100 K, or at least 150 K, or at least 200 K, or at least 250 K, or at least 300 K, or at least 350 K, or at least 400 K, or at least 450 K, or at least 500 K, or at least 550 K, or at least 600 K. The cooling can be achieved at an essentially constant temperate decrease rate. The temperate decrease rate can be at least 10 K/hour, or at least 50 K/hour, or at least 80 K/hour, or at least 100 K/hour, or at least 120 K/hour, or at least 150 K/hour, or at least 180 K/hour, or at least 200 K/hour, or at least 220 K/hour, or at least 250 K/hour, or at least 280 K/hour, or at least 300 K/hour, or at least 320 K/hour, or at least 350 K/hour, or at least 380 K/hour, or at least 400 K/hour, or at least 420 K/hour, or at least 450 K/hour, or at least 480 K/hour, or at least 500 K/hour, or at least 520 K/hour, or at least 550 K/hour, or at least 580 K/hour, or at least 600 K/hour, or at least 650 K/hour, or at least 700 K/hour, or at least 750 K/hour, or at least 800 K/hour. The cooling can be achieved at a variable temperate decrease rate. The essentially constant or variable temperate decrease rate can be controlled by, for example, the flow rate of the coolant.

In some embodiments, the method of manufacturing an article includes annealing the mixture. The mixture is annealed at a third temperature. The third temperature is lower, at a third temperature difference, than the lower of the melting temperature of the first material and that of the second material. The third temperature difference can be at least 1 K, or at least 2 K, or at least 5 K, or at least 8 K, or at least 10 K, or at least 12 K, or at least 15 K, or at least 20 K, or at least 25 K, or at least 30 K, or at least 35 K, or at least 40 K, or at least 45 K, or at least 50 K, or at least 80 K, or at least 100 K, or at least 150 K, or at least 200 K, or at least 250 K, or at least 300 K, or at least 350 K, or at least 400 K, or at least 450 K, or at least 500 K, or at least 550 K, or at least 600 K. In some embodiments, the annealing lasts at least 0.1 hours, or at least 0.5 hours, or at least 1 hour, or at least 1.5 hours, or at least 2 hours, or at least 2.5 hours, or at least 3 hours, or at least 4 hours, or at least 5 hours, or at least 6 hours, or at least 7 hours, or at least 8 hours, or at least 10 hours, or at least 12 hours, or at least 15 hours, or at least 20 hours, or at least 24 hours, or at least 30 hours, or at least 36 hours, or at least 42 hours, or at least 48 hours, or at least 54 hours, or at least 60 hours, or at least 66 hours, or at least 72 hours, or at least 78 hours, or at least 84 hours, or at least 90 hours, or at least 96 hours.

Operation conditions including, for example, the temperate decrease rate (or cooling rate), annealing time and temperature, and the like, or a combination thereof, can effect the microstructure or nanostructure of the article including the microstructure or nanostructure of the matrix and/or of the nanoinclusions. Merely by way of example, annealing time and temperature is proportional to the size growth of the nanoinclusions. In some embodiments, the annealing time and temperature are chosen to achieve desired the microstructure or nanostructure of the article including the microstructure or nanostructure of the matrix and/or of the nanoinclusions. In some embodiments, the annealing are repeated to further improve or adjust the microstructure or nanostructure of the article (e.g., by improving or adjusting the microstructural or nanostructural parameters of the nanoinclusions), at the same condition as the previous annealing process, or at a different condition.

In some embodiments, the method of manufacturing an article includes further cooling and/or further annealing. The cooling can be repeated at least once, at the same condition as the previous cooling process, or at a different condition. The annealing can be repeated, at the same condition as the previous annealing process, or at a different condition.

In some embodiments, the method of manufacturing an article includes doping the article with a dopant. Effective electron donor dopants (n-type dopants) include, for example, lanthanum (La), thulium (Tm), indium (In), iodine (I), and the like. Effective electron acceptor dopants (p-type dopants) include, for example, sodium (Na), potassium (K), thallium (Tl), and the like. The doping can be performed after the heating. In some embodiment, the doping are performed before the cooling. In some embodiment, the doping are performed before the annealing. In some embodiment, the doping are performed after the annealing.

An article manufactured according to the method described herein has improved thermoelectric performance, e.g., improved thermoelectric figure of merit. This can be due to the complexity of the valence band structure and nanostructure effects, as well as optimized combination of carrier density and nanostructure. The article of manufacture can have a thermoelectric figure of merit of 1 or higher. The article of manufacture can have an improved theoretically available power generation efficiency (ηₘₐₓ).

A person of ordinary skill in the art, reading the instant disclosure, would know how to arrange the order and conditions for the cooling, annealing and doping processes to manufacture the described article of manufacture.

Some embodiments of the instant disclosure are directed to a method of using an article of manufacture in a thermoelectric device, wherein the article of manufacture includes a matrix and nanoinclusions, wherein the nanoinclusions are uniformly dispersed in the matrix, and wherein the article of manufacture has a thermoelectric figure of merit zT of at least 1.

In some embodiments, the method of using the article of manufacture includes applying a temperature gradient to the article of manufacture; and collecting electrical energy. In some embodiments, the method of using the article of manufacture includes applying electrical energy to the article of manufacture; and transferring heat from a first space at a first operation temperature to a second space at a second operation temperature, wherein the first operation temperature is lower than the second operation temperature.

Merely by way of example, thermoelectric modules including the article of manufacture disclosed herein are used to harness waste heat from automotive exhaust (500 K-800 K) to produce electricity and reduce CO₂ emissions. The efficiency of such thermoelectric generators is determined by the temperature difference, yielding the Carnot limit, and the material efficiency.

The following examples are for illustrative purposes only and are not intended to limit the scope of the disclosure or its various embodiments in any way.

### EXAMPLES

The following examples are included to demonstrate embodiments disclosed herein. It is appreciated by those of skill in the art that the methodology and compositions disclosed in the examples which follow represent methodology discovered by the inventors to function well in the practice of the disclosure, and thus can be considered to constitute particular modes for its practice. However, those of skill in the art can, in light of the present disclosure, appreciate that many changes can be made in the specific embodiments which are disclosed and still obtain a like or similar result without departing from the spirit and scope of the disclosure.

### Example 1

### Pseudo-Binary Phase Diagram of PbTe-Ag₂Te

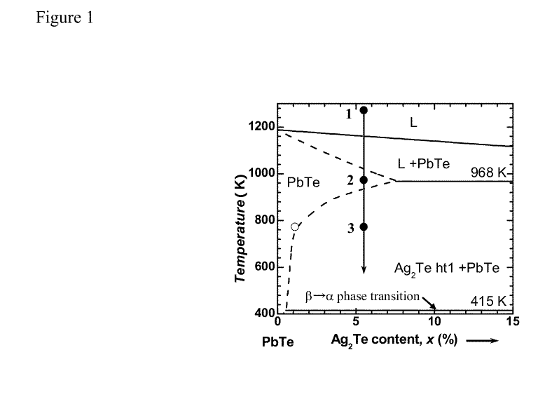

The pseudo-binary phase diagram of PbTe-Ag₂Te (see FIG. 1) shows significant and strongly temperature dependent solubility of Ag₂Te in PbTe. There is a variance in maximum solubility of Ag₂Te in PbTe, which is 7-11 mol. % at the eutectic temperature of 970 K and quickly drops to 1 mol. % at 770 K. From these features, it can be expected that after melting (step 1 in FIG. 1) and homogenizing the solid solution at 970 K (step 2 in FIG. 1), Ag₂Te precipitates can be obtained during a lower temperature anneal at 770 K (step 3 in FIG. 1).

Similar behavior in the PbTe-Sb₂Te₃ phase diagram can be harnessed to yield Widmanstätten precipitates of Sb₂Te₃ in a matrix of PbTe.

### Example 2

### Formation of (PbTe)ₓ(Ag₂Te)ₓ

Pure elements were used for the preparation of (PbTe)_{50-z}(Ag₂Te)_{2z/3} nanocomposites with z=0, 1, 2, 3 and 4 (correspond to the Pb-contents of 50 mol. %, 49 mol. %, 48 mol. %, 47 mol. % and 46 mol. % as shown in the original PbTe-Ag₂Te phase diagram, respectively), which were labeled as Ag1.3 for x=1.3 mol. %, Ag2.7 for x=2.7 mol. %, Ag4.1 for x=4.1 mol. % and Ag5.5 for x=5.5 mol. % in the following discussion (see Table 1 for corresponding formula of (PbTe)₁₋ₓ(Ag₂Te)ₓ with 0≦x≦5.5 mol. %). The purities for the starting Pb (chunk), Ag (shot with size of 2 millimeters) and Te (chunk) were 99.999% or higher (all from Alfa Aesar). The mixture of the elements was loaded into a quartz ampoule followed by sealing under vacuum with a chamber pressure of 10⁻⁵ ton or less. The ampoule was subsequently heated to 1273 K (point 1 in FIG. 1) in a vertical programmable tube furnace at a rate close to 500 K/hour. After soaking at this temperature for approximately 6 hours, the ampoule was cold-water quenched, followed by annealing at 973 K (first annealing, point 2 in FIG. 1) for 2 days and water quenching again. To obtain the precipitates (nanoinclusions) of Ag₂Te from this solid solution prepared at high temperature, the ampoule was re-annealed (second annealing, point 3 in FIG. 1) at 773 K for 3 additional days. The resulting ingots were ground into a fine power then hot pressed at 700 K for an hour to form a dense pellet. The density of the pressed disk was 98% of theoretical value, measured by weight/volume method and confirmed by Archimedes method.

### Example 3

### Doping of (PbTe)ₓ(Ag₂Te)ₓ

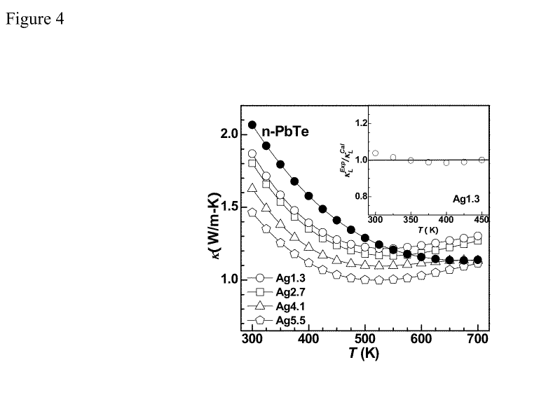

Thermoelectric performance of an article of manufacture for thermoelectric application can be improved by careful control of carrier concentrations through doping. The results on (PbTe)₁₋ₓ(Ag₂Te), nanocomposites indicate that this system is suitable for studying and optimizing thermoelectric transport in PbTe nanocomposites. First, with the addition of Ag₂Te in PbTe, no overwhelming electronic doping effects were found: above 400 K the samples showed intrinsic semiconductor behavior and the transition temperature from extrinsic to intrinsic conduction is independent of Ag content. The concentration of Ag₂Te resulting in nano-precipitates (nanoinclusions) can be adjusted independently from the dopant. Pb/Sb, Pb and the nominally charge balanced NaSb(Bi)Te₂ and AgSbTe₂ can cause significant electronic doping in PbTe. See, for example, J. P. Heremans, C. M. Thrush and D. T. Morelli, Phys. Rev. B, 70, 115334, (2004); J. P. Heremans, C. M. Thrush and D. T. Morelli, J. Appl. Phys., 98, 063703, (2005); J. R. Sootsman, H. Kong, C. Uher and J. J. D. W. P. H. T. C. G. Kanatzidis, Angew. Chem. Int. Ed., 47, 8618, (2008); M. Zhou, J. Li and T. Kita, J. Am. Chem. Soc., 130, 4527, (2008); and A. Gueguen, P. F. P. Poudeu, C. Li, S. Moses, C. Uher, J. He, V. Dravid and K. M., Chem. Mater., 21, 1683, (2009), each of which is hereby incorporated by reference. PbS(SnTe) composites with PbTe can also be intrinsic, or can be extrinsically doped with PbI₂. See, for example, J. Androulakis, C. Lin, H. Kong, C. Uher, C. Wu, T. Hogan, B. A. Cook, T. Caillat, K. M. Paraskevopoulos and M. G. Kanatzidis, J. Am. Chem. Soc., 129, 9780, (2007), which is hereby incorporated by reference. Second, by having minimal electronic contribution to the thermal conductivity, the thermal conductivity reduction due to nanoparticles (nanoinclusions) in PbTe was demonstrated: the lattice contribution to the thermal conductivity was effectively reduced in the whole temperature range (see FIG. 4) regardless of the exact assumption of the Lorenz number L.

Both p- and n-type optimized PbTe thermoelectric materials can be doped with an extrinsic dopant concentration corresponding to an optimal carrier concentration of 10¹⁹-10²⁰ per cubic centimeter. See, for example, I. B. Cadoff and E. Miller, Thermoelectric Materials and Devices. Reinhold Publishing Corporation, New York: Reinhold, 1960, which is hereby incorporated by reference. Effective electron donor dopants in PbTe include La, Tm, In and I, whereas electron acceptors include Na, K, and Tl. More discussion can be found at, for example, I. B. Cadoff and E. Miller, Thermoelectric Materials and Devices. Reinhold Publishing Corporation, New York: Reinhold, 1960; D. L. Partin, J. Appl. Phys., 57, 1997, (1985); B. A. Akimov, E. N. Korobeinikova, L. I. Ryabova, and M. E. Tamm, Sov. Phys. Semicond., 25, 208, (1991); Y. Gelbstein, Z. Dashevsky and M. P. Dariel, Physica B, 363, 196, (2005); and J. P. Heremans, V. Jovovic, E. S. Toberer, A. Saramat, K. Kurosaki, A. Charoenphakdee, S. Yamanaka and G. J. Snyder, Science, 321, 554, (2008), each of which is hereby incorporated by reference. Tl can be a good choice for p-type dopant as it can enhance zT to ˜1.5 in bulk PbTe by distortion of the electronic density of states. See, for example, J. P. Heremans, V. Jovovic, E. S. Toberer, A. Saramat, K. Kurosaki, A. Charoenphakdee, S. Yamanaka and G. J. Snyder, Science, 321, 554, (2008), which is hereby incorporated by reference.

One challenge for controlling the doping in PbTe in the presence of Ag₂Te is the possibility that substitutional Ag at Pb sites or Ag interstitials can compensate other donors. For example, Sb is an n-type dopant when it substitutes Pb in PbTe, but in the presence of Ag₂Te, Sb readily forms compensated AgSbTe₂, which is present as nanoparticles (nanoinclusions) or dissolves into PbTe. Either mechanism reduces the doping effectiveness of Sb.

### Example 4

### Measurements

The phase purity, homogeneity, and microstructure were examined by x-ray diffraction (XRD) and field emission scanning electron microscopy (FESEM) equipped with an energy dispersive spectrometer (EDS). A JEOL 2010F TEM operated at 200 kV was used for the transmission electron microscopy, electron diffraction, and energy dispersive x-ray spectroscopy (EDS, Oxford Inc.) studies. To prepare specimens for TEM, material was mechanically thinned then dimpled in a Gatan 656 Dimple Grinder. Final thinning was conducted using low energy Ar ion milling (Fischione 1010) at cryogenic temperatures. Atom probe tomography was utilized to analyze the compositional homogeneity in the matrix using a LEAP® (Imago Scientific Instruments). This analysis used needle-like specimens with tip diameters of less than 100 nanometers, which was achieved by processing in a FEI Nova600 Dual beam FIB equipped with an “Xtreme Access” micro-manipulator as previously described in, for example, G. B. Thompson, H. L. Fraser and M. K. Miller, Ultramicroscopy, 100, 25, (2004), which is hereby incorporated by reference.

### Example 5

### Microstructure of (PbTe)ₓ(Ag₂Te)ₓ

Four compositions of (PbTe)₁₋ₓ(Ag₂Te), were considered here (x=1.3 mol. %, 2.7 mol. %, 4.1 mol. %, 5.5 mol. %), all of which had compositions (Table 1) greater than the solubility limit for Ag₂Te at the annealing temperature (770 K). After melting (step 1 in FIG. 1) and homogenizing the solid solution at 970 K (step 2 in FIG. 1), Ag₂Te precipitates (nanoinclusions) were obtained during a lower temperature anneal at 770 K (step 3 in FIG. 1). Following this thermal treatment, Ag-rich precipitates (nanoinclusions) were observed to be homogeneously distributed in the PbTe matrix, as shown by field emission scanning electron microscopy images (FIG. 2(a)). As the Ag₂Te content increased, the Ag₂Te was incorporated as a solid solution in the PbTe matrix up to the solubility limit (1 mol. %) at the annealing temperature. Beyond the solubility limit, the volume fraction of Ag₂Te nanoinclusions increased with increasing Ag₂Te content in the mixture, but the Ag content in the PbTe matrix remained constant. The solubility limit was directly observed in the Ag1.3 sample (FIG. 2) where very few precipitates were found (0.2% volume fraction), indicating that most of the Ag₂Te was dissolved into the PbTe matrix when the nominal concentration of Ag₂Te was about 1.3 mol. %. EDS analysis taken from the SEM observation showed that the PbTe matrix for all samples had an average composition close to the nominal one for Ag1.3 sample (Table 1) when annealed at 773 K. Image analysis of the SEM micrographs showed the nano-precipitate (i.e. nanoinclusion) size to be essentially constant across the (PbTe)₁₋ₓ(Ag₂Te)ₓ series. The area fraction of nanoinclusions can thus be used to estimate the phase boundary edge to be at 1 at. % Ag (x-intercept in FIG. 2(b)). XRD patterns in FIG. 2(c) showed the existence of the Ag₂Te phase in nanocomposites with and without La-doping.

TABLE 1
Sample label, the nominal composition, room temperature Hall
carrier density (n_{H}), density and Dulong-Petit heat capacity (Cₚ) for
PbTe—Ag₂Te nanocomposites with and without La-doping.
(Pb_{1-y}La_{y}Te)₁₋ₓ (Ag₂Te)ₓ

| | | | Ag | La | | Density | C_{P} |
|---|---|---|---|---|---|---|---|
| Label | x | y | at % | at % | n_{H} (cm⁻³) | (g/cm³) | (J/g-K) |
| Ag1.3 | 1.34% | 0 | 1.33% | 0 | 5.93 × 10¹⁷ | 7.90 | 0.150 |
| Ag2.7 | 2.70% | 0 | 2.67% | 0 | 6.57 × 10¹⁷ | 8.05 | 0.151 |
| Ag4.1 | 4.08% | 0 | 4.00% | 0 | 6.60 × 10¹⁷ | 7.96 | 0.152 |
| Ag5.5 | 5.48% | 0 | 5.33% | 0 | 7.22 × 10¹⁷ | 8.13 | 0.153 |
| La1 | 5.43% | 0.94% | 5.28% | 0.46% | −2.08 × 10¹⁹ | 7.94 | 0.153 |
| La2 | 5.38% | 1.86% | 5.24% | 0.90% | −2.95 × 10¹⁹ | 8.05 | 0.153 |
| La3 | 5.33% | 2.76% | 5.19% | 1.34% | −3.43 × 10¹⁹ | 8.03 | 0.154 |
| La4 | 5.28% | 3.64% | 5.14% | 1.77% | −4.15 × 10¹⁹ | 8.06 | 0.154 |

The high temperature structure of alpha-Ag₂Te (α-Ag₂Te) contains a face-centered-cubic-like arrangement of Te with Ag cations distributed among a variety of interstitial sites. At 415 K, a slight structural distortion occurs and the β (beta) phase with a monoclinic cell is formed. The lattice mismatch between the Ag₂Te (both modifications) and PbTe crystal structures is close to 2%, suggesting these precipitates (i.e. nanoinclusions) can be semi-coherent and oriented with respect to the matrix. Electron diffraction (FIG. 6(b)) confirms that the precipitates (i.e. nanoinclusions) are the monoclinic beta-Ag₂Te (β-Ag₂Te) phase with the same orientation relationship described for beta-Ag₂Te (β-Ag₂Te) in rocksalt-structured AgSbTe₂ which had a mismatch of about 8-10% in J. D. Sugar and D. L. Medlin, J. Alloys Cmpd., 478, 75, (2009), which is hereby incorporated by reference. Energy Dispersive Spectrometry (EDS) analysis carried out on some large sized precipitates confirms a composition close to Ag₂Te. The compositional details for the samples can be found in Table 1.

To develop robust models for the thermal conductivity, the microstructural geometry was examined. SEM and TEM images indicated that the majority of the precipitates in samples with more than 1.3 mol. % Ag₂Te were plate-like with long dimensions of 100-200 nanometers and short dimensions of 50-100 nanometers. A small fraction of the population observed have at least one dimension as large as 1 micrometer. In the Ag5.5 sample, the average number density of the short plate-like precipitates is 55±30 per cubic micrometer based on TEM observations for which an area density was measured and the thickness of the TEM foil was approximated by measuring distinct features at various tilt angles in the TEM. This gave an inter-precipitate (inter-nanoinclusion) distance of 250 nanometers. The solid-state precipitation mechanism was supported by the observation that only a few precipitates (nanoinclusions) formed in the quickly quenched ingot of the Ag5.5 sample before the final anneal at 773 K.

### Example 6

### Electronic and Thermal Transport of (PbTe)ₓ(Ag₂Te)ₓ

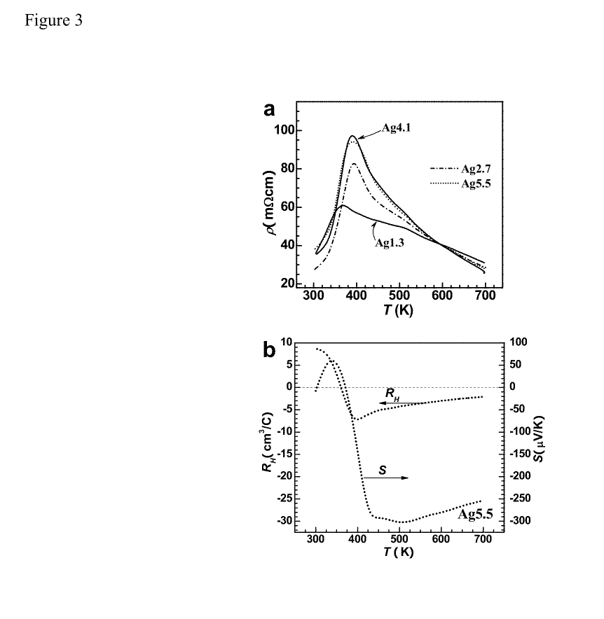

(PbTe)₁₋ₓ(Ag₂Te)ₓ samples discussed in Example 2 and Example 3 were further examined for the electronic and thermal transport properties. FIG. 3(a) reveals that all (PbTe)₁₋ₓ(Ag2Te)ₓ samples exhibited semiconducting behavior with relatively high electrical resistivity of the order 40 mΩ cm at 300 K. The decreasing resistivity above 400 K indicated a transition from extrinsic to intrinsic behavior in all (PbTe)₁₋ₓ(Ag₂Te)ₓ samples. This was also evident from the quick crossover of the Seebeck coefficient as well as the Hall coefficient, as shown in FIG. 3(b) for the Ag5.5 sample, indicating a typical mixed conduction by both electrons and holes. The resistivity peaks can also result from, at least partially, the β (beta)→α (alpha), monoclinic to cubic, phase transition of Ag₂Te at this temperature (see FIG. 1). Ag₂Te may be expected to be a p-type dopant in PbTe in analogy to Na₂Te and K₂Te where Na⁺ or K⁺ substitute for Pb⁺². However, ˜1 mol. % solubility of Ag₂Te in PbTe apparently resulted in compensated defects and very few extrinsic carriers (<10¹⁸ cm⁻³, Table 1). This can be explained by half of the Ag atoms occupying interstitial sites donating one electron compensating for the remaining Ag substituting for Pb. The occurrence of Ag as both an n- and a p-type dopant has been previously reported. See, for example, A. J. Strauss, J. Electronic Materials, 2, 553, (1973), which is hereby incorporated by reference.

Thermal conductivity measurements, shown in FIG. 4 for (PbTe)₁₋ₓ(Ag₂Te)ₓ were obtained from flash diffusivity measurements, using the mass density and the Dulong-Petit approximation for the specific heat capacity. The low electronic conductivity gave a negligible electronic contribution to the thermal conductivity (less than 0.05 W/m-K using the Wiedemann-Franz law) at low temperatures. However, at high temperatures the increasing contribution due to bipolar electronic conductivity led to the increase in thermal conductivity apparent in FIG. 4. This contribution was greatly suppressed in the La-doped samples described below, because La-doping effectively led to conducting behavior dominated by degenerate charge carriers.

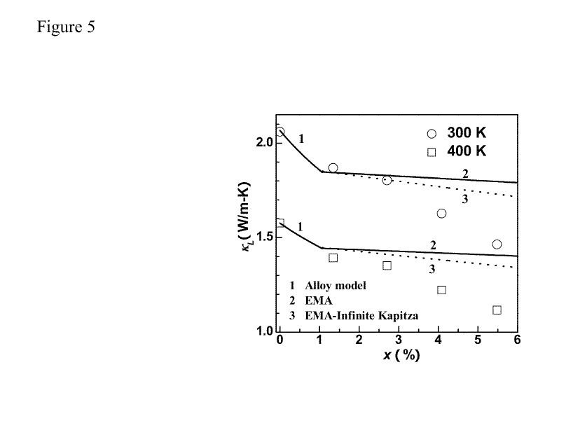

The (PbTe)₁₋ₓ(Ag₂Te)ₓ samples all showed reduced phonon (lattice) thermal conductivity κ_{L} compared to a typical doped PbTe thermoelectric material. This effect can be attributed both to alloy scattering in the PbTe solid solution matrix and to boundary scattering from the nano-precipitates (nanoinclusions). The Ag1.3 sample, which had a low concentration of nanoparticles, has reduced lattice thermal conductivity that largely agrees with that predicted by the Debye-Callaway model (FIG. 5), which is known to accurately predict the effect of point defect scattering in PbTe, skutterudite and half-heusler thermoelectric materials. More disclosure regarding these models and parameters can be found at, for example, Y. K. Koh, C. J. Vineis, S. D. Calawa, M. P. Walsh and D. G. Cahill, Appl. Phys. Lett., 94, 153101, (2009); J. Callaway and H. C. B. von Hc, Phys. Rev., 120, 1149, (1960); P. G. Klemens, Proc. Phys. Soc. (London), Sect. A, 68, 1113, (1955); B. Abeles, Phys. Rev., 131, 1906, (1963); G. P. Meisner, D. T. Morelli, S. Hu, J. Yang and C. Uher, Phys. Rev. Lett., 80, 3551, (1998); and J. Yang, G. P. Meisner and L. Chen, Appl. Phys. Lett., 85, 1140, (2004), each of which is hereby incorporated by reference. In the instant disclosure, the Debye-Callaway model was implemented using the un-doped sample as a reference and accounting for both mass and strain contrast in the doped samples. Additionally, it was assumed that half of the Ag atoms in PbTe occupied an interstitial site tetrahedrally coordinated to Te atoms. The parameters used for the calculation are: Debye temperature 130 K, sound velocity 1432 m/s, lattice constant 6.46 Å and lattice an harmonic constant 65 (a function of Grüneisen parameter). More description about these parameters can be found at, for example, Y. I. Ravich, B. A. Efimova and I. A. Smirnov, Semiconducting Lead Chalcogenides. Plenum, New York, 1970; and G. T. Alekseeva, B. A. Efimova, L. M. Ostrovskaya, O. S. Serebryannikova and M. I. Tsypin, Sov. Phys. Semicond., 4, 1122, (1971), each of which is hereby incorporated by reference. The agreement between the calculated and experimental lattice thermal conductivity is better than 97% for the nearly single phase Ag1.3 material at T<450 K, as shown in the inset of FIG. 4.

The x=1.3 mol. % data (Ag1.3) agreed well with the alloy model because only very few Ag₂Te particles (nanoinclusions) were present, allowing this composition to be treated as a single-phase alloy. However, for greater Ag content, the thermal conductivity continued to drop, which were simply explained with the expected alloy effect. In the pseudo-binary (PbTe)₁₋ₓ(Ag₂Te)ₓ system, compositions of x>1 mol. % falls in the two-phase coexistence region for temperatures lower than 750 K (FIG. 1). For conventional mixed crystals with Kapitza contact thermal resistance, the effective medium approximation (EMA) provides a simple but powerful description of lattice thermal conductivity based on the properties of the individual components, volume fraction and the shape of inclusions. More description about the model for EMA can be found at, for example, C. Nan, R. Birringer, D. R. Clarke and H. Gleiter, J. Appl. Phys., 81, 6692, (1997), which is hereby incorporated by reference. According to the size and number density of Ag₂Te-particles observed by TEM (described above) in the Ag5.5 sample, the estimated volume fraction was 5%, which was very close to 4% as calculated from the nominal composition. Using the nominal volume fraction and the reported thermal conductivity of monoclinic beta-Ag₂Te (β-Ag₂Te), the Ag₂Te concentration dependent lattice thermal conductivity was calculated using the effective medium approximation for spherical inclusions. More description about the calculation can be found at, for example, M. Fujikane, K. Kurosaki, H. Muta and S. Yamanaka, Journal of Alloys and Compounds, 393, 299-301, (2005), which is hereby incorporated by reference. The lattice thermal conductivities of pure Ag₂Te (0.9 W/m-K at 300 K and 0.75 W/m-K at 400 K) were used in the model calculation, which is expected to be close to that of Ag₂Te with dilute solute of PbTe (<1 mol. % PbTe) as indicated by the phase diagram. See, for example, F. W. F, J. Less-Common Met., 13, 579, (1967); and http ://www.asminternational.org/asmenterprise/APD/ViewAPD.aspx?id=950639 provided by ASM Alloy Phase Diagrams Center, each of which is hereby incorporated by reference. The expected thermal conductivity were shown as solid curves in FIG. 5 assuming no Kapitza resistance. If Kapitza resistance was included the expected lattice thermal conductivity κ_{L} dropped only slightly. The dotted curves in FIG. 5 show the limit of infinite Kapitza resistance due to thermally isolated particles or voids.

The experimental lattice thermal conductivity in the Ag₂Te—PbTe nanocomposites was clearly lower than that expected by a composite of alloys, and even below that expected if the interfaces had infinite Kapitza resistance, indicating that the thermal conductivity of the PbTe alloy matrix was reduced by at least one additional mechanism. This reduced κ_{L} arose both from the alloy scattering in the PbTe matrix and the scattering of long mean-free path phonons at the interfaces of the precipitates. Most model calculations and experimental studies have investigated extremely fine (<20 nm) nano-sized particles distributed in a matrix phase to reduce the lattice thermal conductivity. See, for example, Y. K. Koh, C. J. Vineis, S. D. Calawa, M. P. Walsh and D. G. Cahill, Appl. Phys. Lett., 94, 153101, (2009); W. Kim, J. Zide, A. Gossard, D. Klenov and S. Stemmer, Phys. Rev. Lett., 96, 045901, (2006); G. H. Zhu, H. Lee, Y. C. Lan, X. W. Wang, G. Joshi, D. Z. Wang, J. Yang, D. Vashaee, H. Guilbert, A. Pillitteri, M. S. Dresselhaus, G. Chen and Z. F. Ren, Phys. Rev. Lett., 102, 196803, (2009); K. F. Hsu, S. Loo, F. Guo, W. Chen, J. S. Dyck, C. Uher, T. Hogan, E. K. Polychroniadis and M. G. Kanatzidis, Science, 303, 818, (2004); B. Poudel, Q. Hao, Y. Ma, Y. Lan, A. Minnich, B. Yu, X. Yan, D. Wang, A. Muto, D. Vashaee, X. Chen, J. Liu, M. S. Dresselhaus, G. Chen and Z. Ren, Science, 320, 634, (2008); D. M. Rowe, Thermoelectrics Handbook: Macro To Nano. CRC/Taylor & Francis, Boca Raton, 2006; and M. S. Dresselhaus, G. Chen, Z. F. Ren, G. Dresselhaus, A. Henry and J.-P. Fleurial, JOM, Journal of the Minerals, Metals and Materials Society, 61, 86, (2009), each of which is hereby incorporated by reference. The traditional room temperature estimate of the phonon mean free path is only 3 nanometers in PbTe, leading to this emphasis on small nanoparticles, and nanoparticle spacing of the order 10 nanometers. However, a more detailed analysis shows that 50% and 10% of the heat in PbTe at room temperature is carried by the phonons having mean free paths greater than 42 nanometers and 860 nanometers respectively. Indeed, a ˜20% reduction in phonon thermal conductivity can be expected in PbTe by scattering those phonons with mean free paths greater than ˜200 nanometers (the inter-precipitate distances are ˜250 nanometers in the samples here). The total thermal conductivity was reduced in the entire measured temperature range as shown in FIG. 4. The reduction of thermal conductivity κ_{L} was more effective when the concentration of dispersed phase increased, indicating that more phonons were scattered due to the increased density of scattering centers. More description can be found at, for example, M. S. Dresselhaus, G. Chen, Z. F. Ren, G. Dresselhaus, A. Henry and J.-P. Fleurial, JOM, Journal of the Minerals, Metals and Materials Society, 61, 86, (2009); and R. Yang, G. Chen and M. S. Dresselhaus, Phys. Rev. B, 72, 125418, (2005), each of which is hereby incorporated by reference. These features clearly indicate that the lattice thermal conductivity was effectively reduced by adjusting the well-controlled precipitate (nanoinclusions) distribution, even though the particle (nanoinclusion) size is as large as 50-200 nanometers.

The experimental thermal conductivity was also very close to that expected for a supersaturated solid solution of (PbTe)₁₋ₓ(Ag₂Te)ₓ using the Debye-Callaway model described above (not shown in FIG. 5). As point defect and boundary scattering are both effective means of lowering the lattice thermal conductivity, it can be difficult to distinguish the lattice thermal conductivity reduction of non-equilibrium alloying from that due to precipitate formation without a detailed understanding of the microstructure.

### Example 7

### Doping (PbTe)(ₓ(Ag₂Te)ₓ with La and Measurements

La was added as an n-type dopant. More description about La dopant can be found at, for example, K. Ahn, C. Li, C. Uher and M. G. Kanatzidis, Chem. Mater., 21, 1361, (2009), which is hereby incorporated by reference. The La-doped series with composition of (PbLa_{z}Te_{1+z})_{0.945}(Ag₂Te)_{0.055} were identified as La1 for z=1%, La2 for z=2%, La3 for z=3% and La4 for z=4% (see Table 1 for corresponding formula of (Pb_{1-y}La_{y}Te)₁₋ₓ(Ag₂Te)ₓ). The dashed arrow in FIG. 1 shows the composition line of the matrix material (PbTe)_{0.945}(Ag₂Te)_{0.05}, on which the La-doping was carried out. These specimens were prepared using the pre-synthesized Ag5.5 ingot [(PbTe)_{0.945}(Ag₂Te)_{0.055}, after first annealing] and stoichiometric quantities of elemental La (chunk with metal basis purity at 99.9% form Alfa Aesar) and Te, followed by the same melting, water quenching, annealing and hot-pressing procedures used for the undoped series described in Example 2. In an attempt to ensure the stability of the measurements at T>700 K, the pressed disk was annealed for an additional 3 days at 773 K (point 3 in FIG. 1) followed by water quenching before transport properties were measured.

Electrical resistivity and Hall effect were measured by the Van der Pauw technique. A reversible magnetic field of 2 T was used for the Hall effect measurement in the temperature range of 300-675 K. The Hall carrier density was obtained by n_{H}=1/eR_{H}, where R_{H} is the Hall coefficient and e is the electron charge. Seebeck coefficient was obtained by measuring the thermal power under a temperature gradient of 10 K using chromel-niobium thermocouples. Consistent results were obtained both from measurements utilizing constant temperature gradient and measurements at constant average temperature with more than 50 varying temperature differences between +5 K and −5 K. Thermal conductivity was obtained by the measurement of thermal diffusivity using a laser flash method (Netzsch LFA 457). All of the measurements were carried out under vacuum in the temperature range of 300 K-775 K. Heat capacity Cₚ was estimated using the method of Dulong-Petit with a value of 0.15 J/g·K, close to the experimental value from 150 K to 270 K. More description can be found at, for example, D. H. Parkinson and J. E. Quarrington, Proc. Phys. Soc., 67, 569, (1954), which is hereby incorporated by reference. The actual Cₚ value may be 10% higher at 775 K (and corresponding thermoelectric figure of merit zT 10% lower) as reported elsewhere at, for example, M. Zhou, J. Li and T. Kita, J. Am. Chem. Soc., 130, 4527, (2008), which is hereby incorporated by reference. The thermal conductivity κ was then calculated from the experimental density, heat capacity, and the thermal diffusivity. Measurement reproducibility was confirmed by the consistency of the heating and cooling thermal cycles on the same sample.

Repeated measurements were performed on re-synthesized thermoelectric composition (article of manufacture) (La_{0.028}Pb_{0.972}Te)_{0.947}(Ag₂Te)_{0.053} (identified as La3), and the samples with the same composition resulted in a thermoelectric figure of merit zT ranging from 1.5 to 1.7 at 775 K, which can be due to variations of the carrier density. Seebeck coefficient and resistivity measurements on this composition were also confirmed in the temperature range of 300 K-650 K, by using an ULVAC ZEM-3 system. The combined experimental uncertainty for the determination of thermoelectric figure of merit zT was considered to be close to 20%.

### Example 8

### La-Doped (PbTe)ₓ(Ag₂Te)ₓ

La is an n-type dopant in PbTe. More discussion about La can be found at, for example, G. T. Alekseeva, M. V. Vedernikov, E. A. Gurieva, P. P. Konstantinov, L. V. Prokofeva and Y. I. Ravich, Semiconductors, 32, 716, (1998); and K. Ahn, C. Li, C. Uher and M. G. Kanatzidis, Chem. Mater., 21, 1361, (2009), each of which is incorporated herein by reference. La is less likely to be compensated by Ag as there are no known Ag—La—Te compounds. Some charge compensation was observed La-doped PbTe alloyed with Ag metal (Pb₁₋ₓLaₓTe—Ag): electron concentration in Pb_{0.99}La_{0.01}Te dropped from 5×10¹⁹ per cubic centimeter to 1-2×10¹⁹ per cubic centimeter when 5 at.% to 10 at.% of Ag was added. See., for example, K. Ahn, C. Li, C. Uher and M. G. Kanatzidis, Chem. Mater., 21, 1361, (2009), which is hereby incorporated by reference. It has been concluded in the Ahn reference that Pb₁₋ₓLaₓTe—Ag crystallized in a NaCl-type structure without noticeable impurity phase formation, that the lattice parameter continuously decreased with increasing Ag content, and that a zT of close to 1.2 was obtained at 720 K in the (Pb₁₋ₓLaₓTe—Ag) where no evidence of nanoparticles (nanoinclusions) was shown and no evidence of Ag₂Te was seen.

The results of the instant disclosure showed that La was an effective n-type dopant in LaₓPb₁₋ₓTe—Ag₂Te, while retaining the nanocomposite structure. TEM observations on the La-doped sample La3 (FIG. 6(a)) show a similar volume density (close to 50±30 per cubic micrometer) and range of sizes for Ag₂Te particles (nanoinclusions) as the Ag5.5 sample without La. Only in a very small population of precipitates (nanoinclusions) containing Ag, La, and Te were observed via TEM and STEM-EDS. No nanoparticles (nanoinclusions) smaller than 30 nanometers were observed by either TEM or atom probe tomography (APT) on the La3 sample. In other high thermoelectric figure of merit zT nanocomposite systems, smaller nanoparticles (nanoinclusions) were observed. See, for example, K. F. Hsu, S. Loo, F. Guo, W. Chen, J. S. Dyck, C. Uher, T. Hogan, E. K. Polychroniadis and M. G. Kanatzidis, Science, 303, 818, (2004); J. Androulakis, K. F. Hsu, R. Pcionek, H. Kong, C. Uher, J. D'Angelo, A. Downey, T. Hogan and M. G. Kanatzidis, Adv. Mater., 18, 1170, (2006); P. F. P. Poudeu, J. D'Angelo, J. L. Short, T. P. Hogan, and M. G. Kanatzidis, Angew. Chem. Int. Ed., 45, 3835, (2006); J. Androulakis, C. Lin, H. Kong, C. Uher, C. Wu, T. Hogan, B. A. Cook, T. Caillat, K. M. Paraskevopoulos and M. G. Kanatzidis, J. Am. Chem. Soc., 129, 9780, (2007); J. R. Sootsman, H. Kong, C. Uher and J. J. D. W. P. H. T. C. G. Kanatzidis, Angew. Chem. Int. Ed., 47, 8618, (2008); M. Zhou, J. Li and T. Kita, J. Am. Chem. Soc., 130, 4527, (2008); A. Gueguen, P. F. P. Poudeu, C. Li, S. Moses, C. Uher, J. He, V. Dravid and K. M., Chem. Mater., 21, 1683, (2009), each of which is hereby incorporated by reference. A three-dimensional APT reconstruction from the matrix of the La3 sample showed all elements homogenously dispersed in the matrix phase (FIG. 7(a)). To confirm that the Ag and La were randomly distributed within the sample and that no clustering was present in the APT reconstruction, a frequency distribution histogram, which measured composition in many equally sized regions of the data set, was utilized. More discussion about the measurement can be found at, for example, B. A. Akimov, E. N. Korobeinikova, L. I. Ryabova, and M. E. Tamm, Sov. Phys. Semicond., 25, 208, (1991), which is hereby incorporated by reference. The histograms for both Ag and La conformed to a binomial distribution as shown in FIG. 7(b). APT analysis indicated that the matrix of the La3 alloy was 45% Pb, 52% Te, 2% La, and less than 1% Ag was detected in this sample.

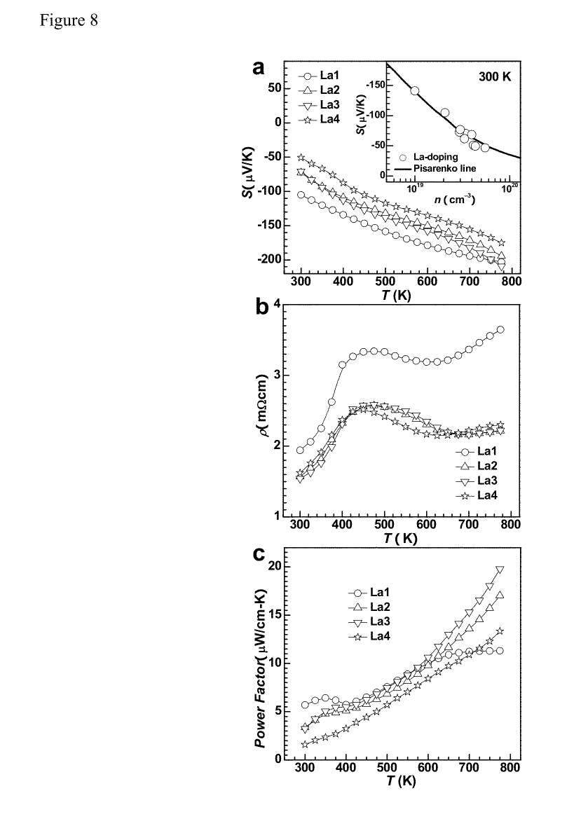

La-doped (PbTe)_{0.945}(Ag₂Te)_{0.055} composites (articles of manufacture) exhibited n-type heavily doped semiconducting behavior in the entire temperature range measured (FIG. 8) consistent with typical n-type doped PbTe. The electrical resistivity p was reduced by more than an order of magnitude as compared with the undoped samples (see FIG. 3(a)) because of the increased carrier density (see Table 1). The measured carrier density of 2×10¹⁹ per cubic centimeter to 4×10¹⁹ per cubic centimeter for most samples was very near the optimum carrier concentration for n-type PbTe (according to I. B. Cadoff and E. Miller, Thermoelectric Materials and Devices. Reinhold Publishing Corporation, New York: Reinhold, 1960, which is hereby incorporated by reference) and corresponds to 0.1% to 0.3% La in the Pb site assuming one La⁺³ substituting for Pb⁺² released one electron to the framework (matrix). These results indicate La is an effective dopant in (PbTe)₁₋ₓ(Ag₂Te)ₓ. Some of the La⁺³ was either compensated by Ag⁺¹ on Pb sites (APT composition shown above) or not incorporated into the matrix (presence of La-rich impurity phases, and there was visible evidence of reaction between La and quartz tube during the high temperature processing). This dopant effectivity of <100% of La can actually be beneficial as it allows finer tuning of carrier concentration through adjustments of the nominal chemical composition. Power factor is defined as S²/ρ.

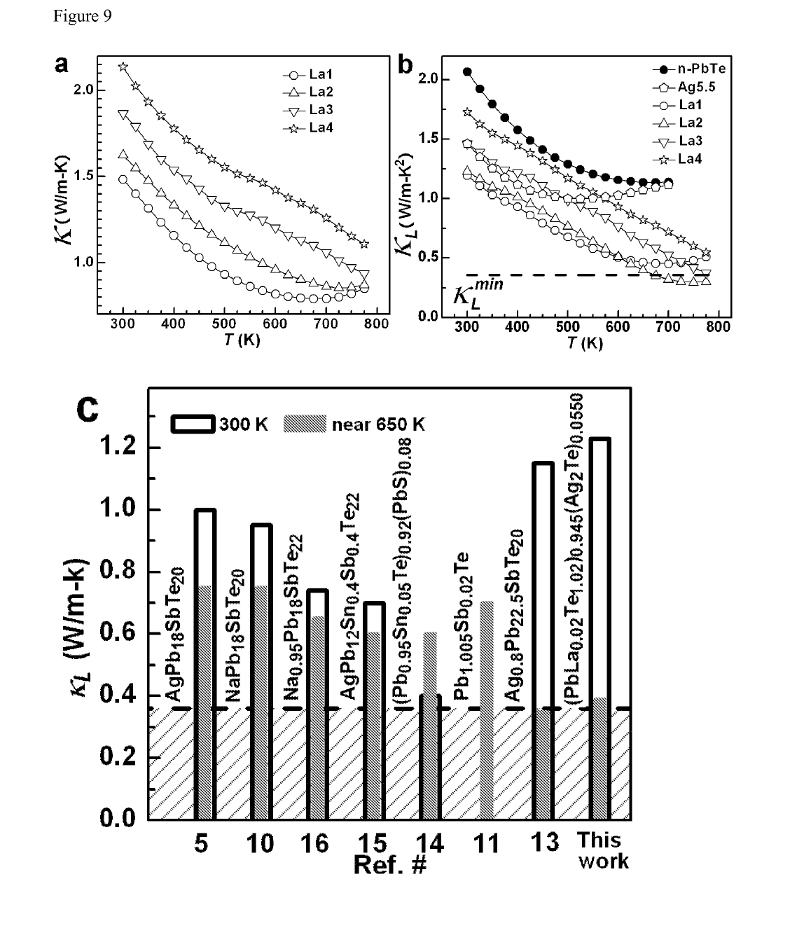

A maximum in electrical resistivity was also found at T close to 400 K in the La-doped series. This feature exhibited a hysteresis between heating up and cooling down measurements, and strengthens as the Ag₂Te concentration was increased. This may result from the beta (β)→alpha (α) monoclinic-to-cubic phase transition of Ag₂Te, in which an obvious resistivity enhancement and other electrical transport abnormalities have been reported in the literature. See, for example, F. F. Aliev, Semiconductors, 37, 1057, (2003), which is hereby incorporated by reference. However, the effect of this transition on lattice thermal conductivity and Seebeck coefficient was very weak (FIG. 8(a) and FIG. 9(c)). For a conservative estimate of zT, the more resistive data collected during cooling was used in the calculations of thermoelectric transport properties.

The well established Pisarenko relation of Seebeck vs. carrier density assuming an acoustic phonon scattering mechanism in bulk PbTe (see, for example, Y. I. Ravich, B. A. Efimova and I. A. Smirnov, Semiconducting Lead Chalcogenides. Plenum, New York, 1970, which is hereby incorporated by reference) gave a good description of the experimental data for La-doped samples (the inset in FIG. 8(a)). This indicated that the usual modeling description for bulk PbTe was unchanged by the addition of Ag₂Te nanoparticles (nanoinclusions). The electron effective masses (m*) were calculated using the experimental Seebeck coefficient and electron density. The calculation details can be found elsewhere at, for example, D. M. Rowe, CRC Handbook of Thermoelectrics. CRC Press, Boca Raton, Fla., 1995, which is hereby incorporated by reference. Both the room temperature m* of 0.3 to 0.4 mₑ (mₑ is the free electron mass) and, importantly, its temperature dependence showed excellent agreement with those of bulk PbTe within the studied carrier density range. With this model, and to accurately assess the lattice thermal conductivity, the composition and temperature dependence of Lorenz number (L) were estimated, assuming the acoustic phonon scattering mechanism was dominant in the entire temperature range. More discussion can be found at, for example, H. A. Lyden, Phys. Rev., 135, A514, (1964); Y. I. Ravich, B. A. Efimova and I. A. Smirnov, Semiconducting Lead Chalcogenides. Plenum, New York, 1970; and D. M. Rowe, CRC Handbook of Thermoelectrics. CRC Press, Boca Raton, Fla., 1995, each of which is hereby incorporated by reference. The calculated reduced Fermi level, η=E_{F}/k_{B}T, where E_{F} and k_{B} are the Fermi level and Boltzmann constant, respectively, gradually decreased with increasing temperature. T is absolute temperature. This indicated a gradual loss of degeneracy when temperature increased, which was consistent with the observed strongly negative temperature dependence of Lorenz number L. The resulting value of 1.6×10⁻⁸ V²/K² at 775 K is very close to the value of 1.5×10⁻⁸ V²/K² for non-degenerate electron gas scattered by acoustic phonons with a classical Boltzmann distribution (see, for example, D. M. Rowe, CRC Handbook of Thermoelectrics. CRC Press, Boca Raton, Fla., 1995, which is hereby incorporated by reference), while the value obtained in the most heavily doped sample (y=3.64%) of close to 2.2×10⁻⁸ V²/K² at room temperature was close to 2.45×10⁻⁸ V²/K² for strongly degenerate electron gas as in a pure metal. The calculated Lorenz number L for La4 sample showed excellent consistency with other models on Lorenz number for n-PbTe with electron density of 5×10¹⁹ per cubic centimeter, in which the effects of both band nonparabolicy and multi-scattering mechanism were taken into account. See, for example, S. Ahmad and S. D. Mahanti, Phys. Rev. B, 81, 165203, (2010), which is hereby incorporated by reference. The Lorenz number increased with increasing doping level in the whole temperature range, because more carriers led to a stronger degeneracy. The Lorenz number L values obtained were noticeably lower than the free electron value of ˜2.45×10⁻⁸ V²/K² that is frequently used. See, for example, J. Androulakis, K. F. Hsu, R. Pcionek, H. Kong, C. Uher, J. D'Angelo, A. Downey, T. Hogan and M. G. Kanatzidis, Adv. Mater., 18, 1170, (2006); P. F. P. Poudeu, J. D'Angelo, J. L. Short, T. P. Hogan, and M. G. Kanatzidis, Angew. Chem. Int. Ed., 45, 3835, (2006); J. Androulakis, C. Lin, H. Kong, C. Uher, C. Wu, T. Hogan, B. A. Cook, T. Caillat, K. M. Paraskevopoulos and M. G. Kanatzidis, J. Am. Chem. Soc., 129, 9780, (2007); M. Zhou, J. Li and T. Kita, J. Am. Chem. Soc., 130, 4527, (2008); and A. Gueguen, P. F. P. Poudeu, C. Li, S. Moses, C. Uher, J. He, V. Dravid and K. M., Chem. Mater., 21, 1683, (2009), each of which is incorporated by reference.

With the measured thermal diffusivity, density and Dulong-Petit heat capacity (Table. 1), the total thermal conductivity κ (sum of lattice thermal conductivity κ_{L} and electronic thermal conductivity κ_{E}) was determined as shown in FIG. 9(a). The lattice thermal conductivity was obtained by subtracting the electronic component (κ_{E}=LT/ρ, where L, T and ρ are Lorenz number, absolute temperature and electrical resistivity, respectively) from total thermal conductivity κ. Very low lattice thermal conductivities of close to 0.4 W/m-K were achieved at T>650 K in the La2 and La3 samples (FIG. 9(b)), approaching the “minimal thermal conductivity” value of lattice thermal conductivity κ_{L} close to 0.36 W/m-K as calculated by the approach of Cahill (Y. K. Koh, C. J. Vineis, S. D. Calawa, M. P. Walsh and D. G. Cahill, Appl. Phys. Lett., 94, 153101, (2009), which is hereby incorporated by reference). Below 500 K the lattice thermal conductivity of the La3 sample was very similar to that of the undoped Ag5.5 sample. This can be because large nanoparticles (nanoinclusions) were retained. Above 500K the calculated lattice thermal conductivity κ_{L} of the La3 sample was lower than that of the Ag5.5 sample. This can be because of the lack of bipolar thermal conduction in the heavily doped La3 sample. The value of lattice thermal conductivity κ_{L} increased as the nominal La content increased. This can be explained by a reduced alloy phonon scattering. It can be expected that electron-donating La³⁺ on Pb-site defects can reduce the concentration of electron-donating Ag-interstitials by way of, for example, increasing the concentration of electron accepting Ag⁺ on the Pb site. As the interstitial Ag provides the most effective scattering of any of these point defects, the net result can be less point defect scattering.

Comparisons of lattice thermal conductivity κ_{L} for the large nanoparticle (nanoinclusion) La2 sample with small nanoparticle (nanoinclusion) PbTe-based nanocomposites of the optimized thermoelectric compositions reported in the literature (FIG. 9(c)) indicated that the small nanoparticles (<20 nanometers) were effective at reducing lattice thermal conductivity κ_{L} near room temperature. The large nanoparticles (nanoinclusions) (100 nanometers to 200 nanometers) were effective at higher temperature where thermoelectric figure of merit zT is larger. The comparison was based on the Lorenz number L and lattice thermal conductivity κ_{L} that were recalculated using the method discussed above and the transport data from the literature. See, for example, K. F. Hsu, S. Loo, F. Guo, W. Chen, J. S. Dyck, C. Uher, T. Hogan, E. K. Polychroniadis and M. G. Kanatzidis, Science, 303, 818, (2004); J. Androulakis, K. F. Hsu, R. Pcionek, H. Kong, C. Uher, J. D'Angelo, A. Downey, T. Hogan and M. G. Kanatzidis, Adv. Mater., 18, 1170, (2006); P. F. P. Poudeu, J. D'Angelo, J. L. Short, T. P. Hogan, and M. G. Kanatzidis, Angew. Chem. Int. Ed., 45, 3835, (2006); J. Androulakis, C. Lin, H. Kong, C. Uher, C. Wu, T. Hogan, B. A. Cook, T. Caillat, K. M. Paraskevopoulos and M. G. Kanatzidis, J. Am. Chem. Soc., 129, 9780, (2007); M. Zhou, J. Li and T. Kita, J. Am. Chem. Soc., 130, 4527, (2008); J. R. Sootsman, H. Kong, C. Uher and J. J. D. W. P. H. T. C. G. Kanatzidis, Angew. Chem. Int. Ed., 47, 8618, (2008); and A. Gueguen, P. F. P. Poudeu, C. Li, S. Moses, C. Uher, J. He, V. Dravid and K. M., Chem. Mater., 21, 1683, (2009), each of which is hereby incorporated by reference. As compared with those studies, PbTe—AgSbTe₂ (LAST) annealed for very long time (one-month) resulted in a higher lattice thermal conductivity κ_{L} at room temperature but lower lattice thermal conductivity κ_{L} at high temperature, which was similar to the La2 sample. Furthermore, it was also found the size of the nanoparticles (nanoinclusions) increased up to 50 nanometers during the long period annealing. See, M. Zhou, J. Li and T. Kita, J. Am. Chem. Soc., 130, 4527, (2008), which is hereby incorporated by reference. PbS(SnTe)—PbTe samples showed large structures (300 nanometers-600 nanometers in length) that themselves contained <20 nanometers nanoparticles or lamellae (nanoinclusions) different in nature from the much larger features described in the instant disclosure or elsewhere. See, for example, J. Androulakis, C. Lin, H. Kong, C. Uher, C. Wu, T. Hogan, B. A. Cook, T. Caillat, K. M. Paraskevopoulos and M. G. Kanatzidis, J. Am. Chem. Soc., 129, 9780, (2007); and T. Ikeda, L. A. Collins, V. A. Ravi, F. S. Gascoin, S. M. Haile and G. J. Snyder, Chem. Mater., 19, 763-767, (2007), each of which is incorporated by reference. Nanoparticles (nanoinclusions) formed from long-time anneals at elevated temperatures were likely to be more stable at high temperatures than nanoparticles (nanoinclusions) precipitated at lower temperatures. Small particles (nanoinclusions) also tend to form at lower temperatures than larger particles (nanoinclusions).

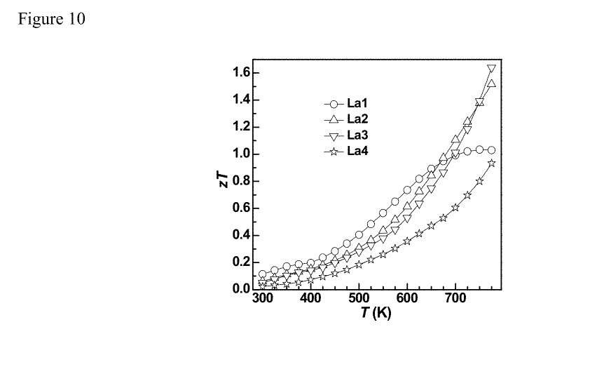

FIG. 10 showed the thermoelectric figure of merit zT for these La-doped (PbTe)_{0.945}(Ag₂Te)_{0.055} samples described above. Samples with Hall carrier densities near 3×10¹⁹ per cubic centimeters showed peak zT values of 1.6 at 775 K. By comparison, conventional n-type PbTe had a peak thermoelectric figure of merit zT of close to 0.8 at 675 K. This peak zT temperature was clearly within a two-phase region where the nanoparticle (nanoinclusion) phase was thermodynamically stable and not adsorbed into the PbTe matrix. The nanoparticles (nanoinclusions) may continue to slowly coarsen. Lower lattice thermal conductivity κ_{L} and thus higher thermoelectric figure of merit zT at some temperatures can be obtained by including smaller (e.g., <50 nanometers) precipitates (nanoinclusions) in addition to the large (e.g., 50- 200 nanometers) precipitates (nanoinclusions) by way of, for example, altering the chemical composition or processing. The relatively low mobility in the lower temperature range can result in the rapidly rising thermoelectric figure of merit zT with temperature.

High thermoelectric figure of merit zT at T>650 K in La doped PbTe-Ag₂Te nanocomposites with an appropriate density of relatively large (100 nanometers -200 nanometers) nanoparticles (nanoinclusions) originated from exceptionally low lattice thermal conductivity κ not found in many related systems with small (<20 nanometers) nanoparticles (nanoinclusions). Undoped PbTe-Ag₂Te nanocomposites demonstrated this effect without the complication of the electronic component κ_{E} to the thermal conductivity. With the combination of independent carrier concentration optimization by La-doping, the thermoelectric figure of merit zT in La- doped PbTe-Ag₂Te nanocomposites reached as high as 1.6 at 775 K. This and similar synthetic approaches, based on both considerations of the equilibrium phase diagram and precipitation kinetics as well as careful control of the dopant chemistry, can be broadly applicable to other thermoelectric material systems.

### Example 9

### Doping (PbTe)ₓ(Ag₂Te)ₓ with Na and Measurements

P-type PbTe/Ag₂Te nanocomposites were obtained by Na-doping (PbTe:Na/Ag₂Te). PbTe/Ag₂Te nanocomposites with a composition of (PbTe)_{0.945}(Ag₂Te)_{0.055} were pre-synthesized as described above and elsewhere (for example, Y. Pei, J. Lensch-Falk, E. S. Toberer, D. L. Medlin, G. J. Snyder, Adv Funct Mater 2011, 21, 241, which is hereby incorporated by reference) and then used as starting materials for making PbTe:Na/Ag2Te together with appropriate amounts of Na and Te metals. The nominal concentration of Na (normalized to Pb) is 0˜3 at % and the final samples for this study were synthesized with the same method as described above, including sealing, melting, quenching, annealing and hot pressing. Phase components were checked using X-ray diffraction and scanning electron microscopy (SEM) equipped with an energy dispersive spectrometer (EDS).

Hot pressed disk-shape samples with relative density of 98% or higher were used for the measurements. Details on measuring the transport properties are described above and elsewhere. See, for example, Y. Pei, A. LaLonde, S. Iwanaga, G. J. Snyder, Energ Environ Sci (2011), DOI: 10.1039/c0ee00456a; and Y. Pei, J. Lensch-Falk, E. S. Toberer, D. L. Medlin, G. J. Snyder, Adv Funct Mater 2011, 21, 241, each of which is hereby incorporated by reference. The heat capacity Cp in k_{B} per atom was calculated to be 3.07+4.7×10⁻⁴×(T/K−300)), which can be accurate for lead chalcogenides. See, for example, R. Blachnik, R. Igel, Z Naturforsch B 1974, B 29, 625; M. Zhou, J. F. Li, T. Kita, J Am Chem Soc (2008), 130, 4527; and Y. Pei, A. LaLonde, S. Iwanaga, G. J. Snyder, Energ Environ Sci 2011, DOI: 10.1039/c0ee00456a, each of which is hereby incorporated by reference. The thermal conductivity for most of the recently reported high zT PbTe materials was determined using a heat capacity of or close to the Dulong-Petit approximation by +/−5%. See, for example, J. Heremans, V. Jovovic, E. Toberer, A. Saramat, K. Kurosaki, A. Charoenphakdee, G. J. Snyder, Science (2008), 321, 554; P. F. P. Poudeu, A. Gueguen, C. I. Wu, T. Hogan, M. G. Kanatzidis, Chem Mater (2010), 22, 1046; and Y. Pei, J. Lensch-Falk, E. S. Toberer, D. L. Medlin, G. J. Snyder, Adv Funct Mater (2011), 21, 241, each of which is hereby incorporated by reference. It should be noted that this method determines a value close to 10% higher than the Dulong-Petit law (3 kB per atom) at T>700 K. The uncertainty for each measurement of Seebeck coefficient S, and thermal conductivity κ is close to 5%, resulting in a combined error close to 20% in thermoelectric figure of merit zT-determination.

### Example 10

### Na-Doped (PbTe)ₓ(Ag₂Te)ₓ

Annealing the high temperature oversaturated solid solution phase of PbTe/Ag₂Te in the low temperature, two-phase region created homogenously distributed Ag₂Te nanoinclusions in a PbTe matrix. FIG. 11 showed the typical nanostructure for both the as cast material and hot pressed pellet of Na-doped PbTe/Ag₂Te. The result was consistent with the literature. More discussion about the annealing and nanostructures can be found at, for example, F. Wald, Journal of the less-common metals (1967), 13, 579; R. Blachnik, B. Gather, Journal of the less-common metals 1978, 60, 25; and J. Lensch-Falk, J. Sugar, M. Hekmaty, D. Medlin, J Alloy Compd (2010), 504, 37, each of which is hereby incorporated by reference.

Similar to PbTe:Na (PbTe doped with Na), Na was found to be an effective p-type dopant in PbTe/Ag₂Te as indicated by the Hall coefficient (R_{H}) and Seebeck coefficient S measurements. The doping solubility of Na in PbTe/Ag₂Te was found to be much smaller than in pure PbTe. The measured room temperature Hall density (p_{H}=1/eR_{H}, e is the electron charge) in PbTe:Na/Ag₂Te was much smaller than that in PbTe:Na. The nominal concentrations of Na were comparable in PbTe:Na/Ag₂Te and previous PbTe:Na. The measured hall density p_{H} in PbTe:Na/Ag₂Te did not exceed 4×10¹⁹ per cubic centimeter, while room temperature Hall density p_{H} can be as high as 14×10¹⁹ per cubic centimeter (according to, for example, Y. Pei, A. LaLonde, S. Iwanaga, G. J. Snyder, Energ Environ Sci 2011, DOI: 10.1039/c0ee00456a, which is hereby incorporated by reference). The most heavily doped samples with room temperature Hall density p_{H} of 2.5, 3.1 and 3.7×10¹⁹ per cubic centimeter were used for following discussions and marked as 2 .5e19, 3.1e19 and 3.7e19, respectively.

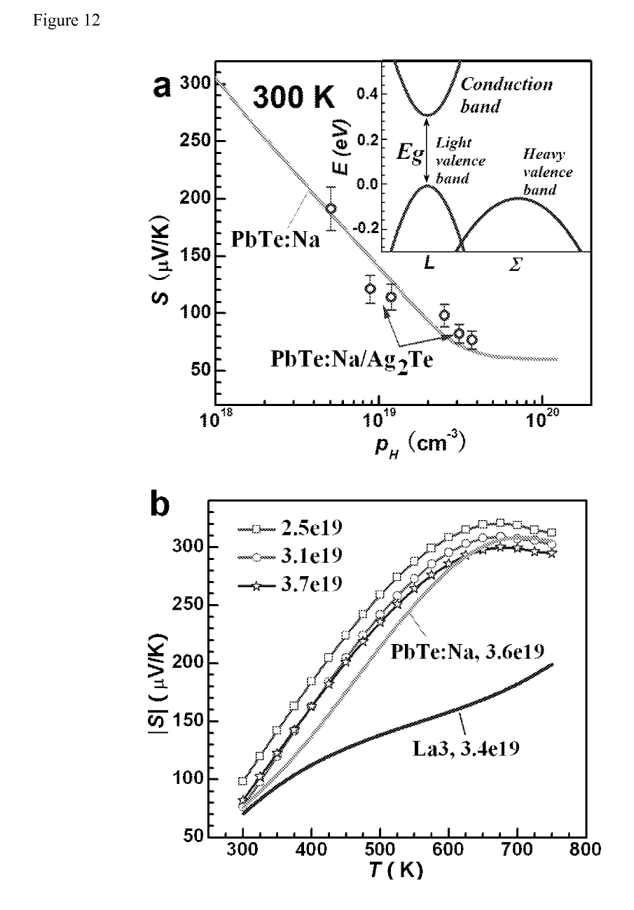

The room temperature Seebeck coefficient S versus Hall density p_{H} (Pisarenko plot, solid curve in FIG. 12(a)) provided a powerful description of the transport properties and the band structure for PbTe. Almost every measurement published on p-type normal bulk PbTe falls on this Pisarenko line, as do the present results within the measurement uncertainty (FIG. 12(a)). More discussion about the correlation can be found at, for example, Y. I. Ravich, B. A. Efimova, I. A. Smirnov, Semiconducting lead chalcogenides, Plenum Press, New York 1970, which is hereby incorporated by reference. Similar to the results found in La-doped PbTe/Ag₂Te (PbTe:La/Ag₂Te) as described above and elsewhere (for example, Y. Pei, J. Lensch-Falk, E. S. Toberer, D. L. Medlin, G. J. Snyder, Adv Funct Mater 2011, 21, 241, which is hereby incorporated by reference), neither doping with Na nor introducing Ag₂Te altered the band structure of PbTe.

The Seebeck coefficient S was flattening at high doping levels (Hall density P_{H}>3×10¹⁹ per cubic centimeter). This can be due to the complex valence structure as shown in the inset of FIG. 12(a). Furthermore, the energy of the light valence band is lowered with increasing temperature and moved below the heavy valence band at close to 450 K. The electronic transport, optical spectroscopy and other properties of p-PbTe can be due to this two-valence-band mode. See, for example, Y. I. Ravich, B. A. Efimova, I. A. Smirnov, Semiconducting lead chalcogenides, Plenum Press, New York 1970; G. Nimtz, B. Schlicht, Springer Tracts in Modern Physics 1983, 98, 1; Y. I. Ravich, in Lead Chalcogenides: Physics and Applications, (Ed: D. Khokhlov), Taylor & Fransics Group, New York 2003, 1; R. S. Allgaier, J Appl Phys 1961, 32, 2185; A. J. Crocker, L. M. Rogers, J Phys-Paris 1968, 29, C4; V. I. Kaidanov, R. B. Melnik, I. A. Chernik, A. A. Kosulina, Sov Phys Semicond+ 1969, 2, 1474; R. N. Tauber, A. A. Machonis, I. B. Cadoff, J Appl Phys 1966, 37, 4855; J. Androulakis, I. Todorov, D. Y. Chung, S. Ballikaya, G. Y. Wang, C. Uher, M. Kanatzidis, Phys Rev B (2010), 82; and Y. Pei, A. LaLonde, S. Iwanaga, G. J. Snyder, Energ Environ Sci (2011), DOI: 10.1039/c0ee00456a, each of which is hereby incorporated by reference.

Rather than a general Seebeck coefficient S being proportional to absolute temperature T, Seebeck coefficient S increased significantly (FIG. 12(b)), particularly at high temperatures. This can be due to the increasing contribution of the heavy mass carriers due to Fermi broadening. The analogous n-type material (PbTe:La/Ag₂Te, La3) had a much lower Seebeck coefficient than p-type PbTe:Na/Ag₂Te. This can be due to the lack of conduction band complexity. These PbTe:Na/Ag₂Te samples showed a roughly unchanged Seebeck coefficient S with respect to PbTe:Na at similar doping levels, which further confirmed the above discussion that Ag₂Te inclusions did not affect the band structure of PbTe.

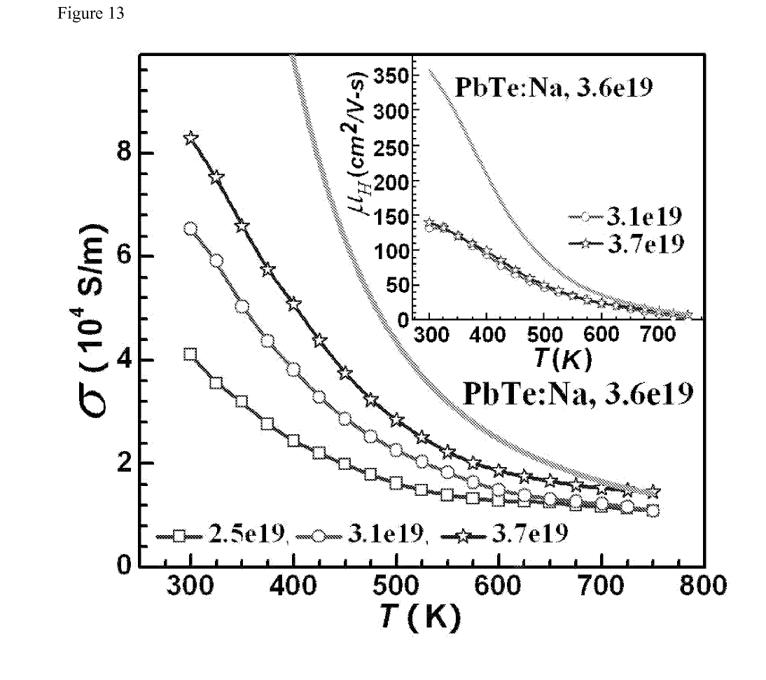

It is reasonable to observe a reduced mobility of PbTe:Na/Ag₂Te as compared with PbTe:Na, due to both the enhanced scattering of carriers at the phase boundaries and the enhanced point defect scattering in the matrix phase. More discussion can be found at, for example, F. Wald, Journal of the less-common metals (1967), 13, 579; and Y. Pei, J. Lensch-Falk, E. S. Toberer, D. L. Medlin, G. J. Snyder, Adv Funct Mater (2011), 21, 241, each of which is hereby incorporated by reference. Shown in the inset of FIG. 13 was the Hall mobility μ_{H} data of PbTe:Na/Ag₂Te samples with Hall density p_{H}>3×10¹⁹ per cubic centimeter along with a comparison to PbTe:Na with similar Hall density p_{H}. These PbTe:Na/Ag₂Te nanocomposites had similar Hall mobility μ_{H} in the same temperature range, and converged with PbTe:Na samples at high temperatures. This can be due to that scattering of carriers in these materials is always dominated by acoustic phonons at high temperatures. As a result, the electrical conductivity of PbTe:Na/Ag₂Te nanocomposites is lower than that of PbTe:Na (FIG. 12) at low temperatures. Similar to PbTe:Na, the electrical conductivity a dropped significantly. This is normally expected for a system dominated by acoustic phonon scattering with increasing temperature, which can be well explained by the increasing carriers from the heavy band that have lower mobility. With similar Hall mobility μ_{H}, increasing Hall density p_{H} resulted in higher electrical conductivity a in PbTe:Na/Ag₂Te nanocomposites, as shown in FIG. 13.

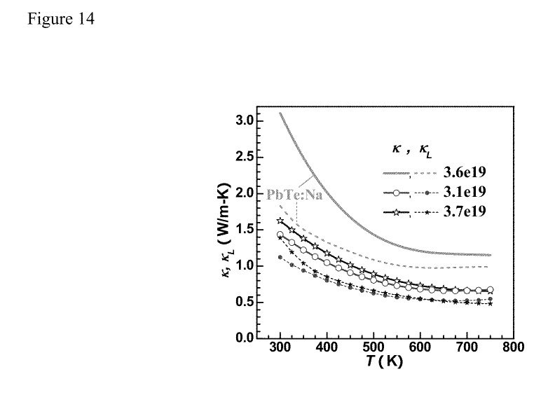

As can be seen in FIG. 14, the thermal conductivity κ was reduced by close to 50% in roughly the entire measured temperature range due to the Ag₂Te nanoinclusions. The Hall density p_{H} of all the samples was similar and found to be close to 3.5×10¹⁹ per cubic centimeter. To avoid the ambiguity of bipolar thermal conductivity and for the sake of clarity, only heavily doped samples were shown in FIG. 14.

The observed reduction in thermal conductivity κ can be, at least, partly due to the reduced electrical conductivity a and thus a reduced electronic component κ_{E} to the thermal conductivity κ as well. It is difficult to accurately estimate the κ_{E} via the Wiedemann-Franz law (κ_{E}=LσT, where L, σ and T are the Lorenz number, electrical conductivity, and absolute temperature, respectively) because of the difficulty in determining the Lorenz number L in p-PbTe due to the complex valence band structure and non-parabolicity of these bands. More discussion about these issues can be found at, for example, I. A. Smirnov, Y. I. Ravich, Sov Phys Semicond+ (1967), 1, 739; I. A. Smirnov, M. N. Vinogradova, N. V. Kolomoets, L. M. Sysoeva, Soviet Physics Solid State, Ussr (1968), 9, 2074; and Y. I. Ravich, B. A. Efimova, I. A. Smirnov, Semiconducting lead chalcogenides, Plenum Press, New York (1970), each of which is hereby incorporated by reference. For simplicity, an estimation of Lorenz number L was made using a single parabolic band (SPB) model assuming an acoustic phonon scattering mechanism, which resulted in a Lorenz number L with a deviation of less than 10% when compared to a more rigorous single non-parabolic band and multiple band model calculation. More discussion regarding the models can be found at, for example, I. A. Smirnov, M. N. Vinogradova, N. V. Kolomoets, L. M. Sysoeva, Soviet Physics Solid State, Ussr (1968), 9, 2074; C. M. Bhandari, D. M. Rowe, in CRC handbook of thermoelectrics, (Ed: D. M. Rowe), CRC Press, Boca Raton, Fla. (1995), 43; S. Ahmad, S. D. Mahanti, Phys Rev B (2010), 81, 165203; and Y. Pei, J. Lensch-Falk, E. S. Toberer, D. L. Medlin, G. J. Snyder, Adv Funct Mater (2011), 21, 241, each of which is hereby incorporated by reference.

By subtracting the electronic component κ_{E} from the total thermal conductivity κ, the obtained lattice component κ_{L} was calculated and given in FIG. 14. The introduction of nanoinclusions effectively reduced the lattice thermal conductivity κ_{L}. This can be due to the enhanced scattering of phonons at boundaries. More discussion for the correlation can be found at, for example, K. F. Hsu, S. Loo, F. Guo, W. Chen, J. S. Dyck, C. Uher, T. Hogan, E. K. Polychroniadis, M. G. Kanatzidis, Science (2004), 303, 818; M. G. Kanatzidis, Chem Mater (2010), 22, 648; Y. Pei, J. Lensch-Falk, E. S. Toberer, D. L. Medlin, G. J. Snyder, Adv Funct Mater 2011, 21, 241, each of which is hereby incorporated by reference. The extremely low lattice thermal conductivity κ_{L} of close to 0.5 W/m-K at T>600 K was approaching the theoretical minimum allowed value of 0.36 W/m-K according to, for example, P. F. P. Poudeu, A. Gueguen, C. I. Wu, T. Hogan, M. G. Kanatzidis, Chem Mater (2010), 22, 1046; Y. Pei, J. Lensch-Falk, E. S. Toberer, D. L. Medlin, G. J. Snyder, Adv Funct Mater (2011), 21, 241, each of which is hereby incorporated by reference. The total thermal conductivity κ of PbTe:Na/Ag₂Te nanocomposites was even lower than the lattice thermal conductivity κ_{L} of PbTe :Na.

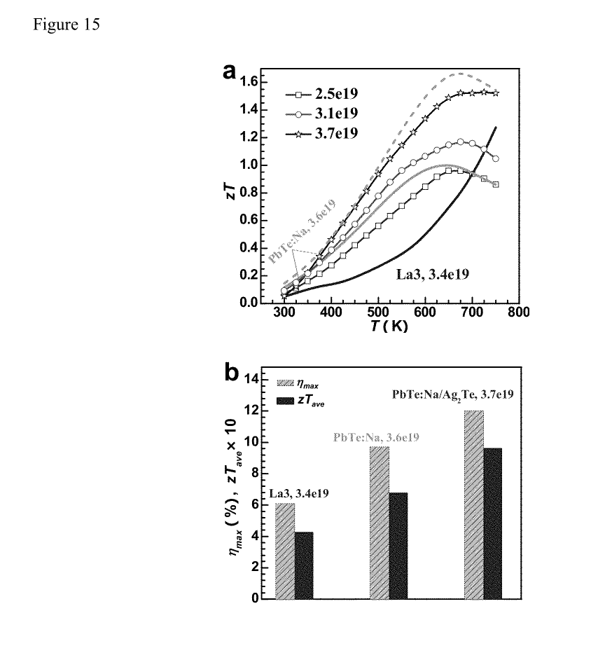

As compared with La-doping discussed above (using the same estimation of heat capacity Cₚ), Na-doping in PbTe/Ag₂Te nanocomposites included the electronic effect of complex band structure for better electronic transport properties, therefore resulted in a significant enhancement of the thermoelectric figure of merit zT, particularly at low temperatures (FIG. 15(a)). Alternatively, compared with PbTe:Na, introducing Ag₂Te nanoinclusions significantly reduced the thermal conductivity κ (FIG. 14) and thus increased thermoelectric figure of merit zT (FIG. 15(a)) in the entire temperature range investigated. This was further evidenced by the excellent convergence of the measured thermoelectric figure of merit zT of the PbTe:Na/Ag₂Te sample with Hall density p_{H}=3.7×10¹⁹ per cubic centimeter and the thermoelectric figure of merit zT curve (dashed curve), which was generated simply assuming a lattice thermal conductivity κ_{L} of PbTe:Na/Ag₂Te with Hall density p_{H}=3.7×10¹⁹ per cubic centimeter for PbTe:Na with Hall density p_{H}=3.6×10¹⁹ per cubic centimeter.

Most importantly, the current effort of combining both complex band structure and nanostructures enabled a thermoelectric figure of merit zT higher than 1.5 at T>650 K. Moreover, as shown in FIG. 15(b), the average thermoelectric figure of merit zT and the theoretically available power generation efficiency (ηₘₐₓ) of PbTe:Na/Ag₂Te, were increased by close to 100-40% when compared to PbTe:La/Ag₂Te and PbTe:Na. Here, the estimations of average thermoelectric figure of merit zT and theoretically available power generation efficiency ηₘₐₓ took into account the thermoelectric compatibility effect described at, for example, G. J. Snyder, in Thermoelectrics handbook: macro to nano, (Ed: D. M. Rowe), CRC/Taylor & Francis, Boca Raton 2006, 1; G. J. Snyder, Appl Phys Lett 2004, 84, 2436; G. J. Snyder, T. Ursell, Phys Rev Lett 2003, 91, 148301, which is hereby incorporated by reference.

Band structure complexity and nanostructured effects are simultaneously considered as an effective approach for improving thermoelectric performance. As is demonstrated in PbTe:Na/Ag₂Te, a peak thermoelectric figure of merit zT higher than 1.5 and significant enhancements of average thermoelectric figure of merit zT/thermoelectric efficiency were realized. Further optimizing the combination of carrier density and nanostructure control can result in an even higher thermoelectric performance in similar PbTe materials.

As will be appreciated by one skilled in the art the elements and structures disclosed here could be used in many combinations and appreciate that these form part of the current invention.

The various methods and techniques described above provide a number of ways to carry out the application. Of course, it is to be understood that not necessarily all objectives or advantages described can be achieved in accordance with any particular embodiment described herein. Thus, for example, those skilled in the art will recognize that the methods can be performed in a manner that achieves or optimizes one advantage or group of advantages as taught herein without necessarily achieving other objectives or advantages as taught or suggested herein. A variety of alternatives are mentioned herein. It is to be understood that some preferred embodiments specifically include one, another, or several features, while others specifically exclude one, another, or several features, while still others mitigate a particular feature by inclusion of one, another, or several advantageous features.

Furthermore, the skilled artisan will recognize the applicability of various features from different embodiments. Similarly, the various elements, features and steps discussed above, as well as other known equivalents for each such element, feature or step, can be employed in various combinations by one of ordinary skill in this art to perform methods in accordance with the principles described herein. Among the various elements, features, and steps some will be specifically included and others specifically excluded in diverse embodiments.

Although the application has been disclosed in the context of certain embodiments and examples, it will be understood by those skilled in the art that the embodiments of the application extend beyond the specifically disclosed embodiments to other alternative embodiments and/or uses and modifications and equivalents thereof.

In some embodiments, the terms “a” and “an” and “the” and similar references used in the context of describing a particular embodiment of the application (especially in the context of certain of the following claims) can be construed to cover both the singular and the plural. The recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (for example, “such as”) provided with respect to certain embodiments herein is intended merely to better illuminate the application and does not pose a limitation on the scope of the application otherwise claimed. No language in the specification should be construed as indicating any non-claimed element essential to the practice of the application.

Preferred embodiments of this application are described herein, including the best mode known to the inventors for carrying out the application. Variations on those preferred embodiments will become apparent to those of ordinary skill in the art upon reading the foregoing description. It is contemplated that skilled artisans can employ such variations as appropriate, and the application can be practiced otherwise than specifically described herein. Accordingly, many embodiments of this application include all modifications and equivalents of the subject matter recited in the claims appended hereto as permitted by applicable law. Moreover, any combination of the above-described elements in all possible variations thereof is encompassed by the application unless otherwise indicated herein or otherwise clearly contradicted by context.

All patents, patent applications, publications of patent applications, and other material, such as articles, books, specifications, publications, documents, things, and/or the like, referenced herein are hereby incorporated herein by this reference in their entirety for all purposes, excepting any prosecution file history associated with same, any of same that is inconsistent with or in conflict with the present document, or any of same that may have a limiting affect as to the broadest scope of the claims now or later associated with the present document. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the application disclosed herein are illustrative of the principles of the embodiments of the application. Other modifications that can be employed can be within the scope of the application. Thus, by way of example, but not of limitation, alternative configurations of the embodiments of the application can be utilized in accordance with the teachings herein. Accordingly, embodiments of the present application are not limited to that precisely as shown and described.

1. An article of manufacture comprising a matrix and nanoinclusions, wherein the nanoinclusions are dispersed in the matrix, and wherein the article of manufacture has a thermoelectric figure of merit (zT) of at least 1.

2. The article of manufacture of claim 1, wherein the article of manufacture has a thermoelectric figure of merit (zT) of at least 1.5.

3. The article of manufacture of claim 1 or claim 2, wherein the matrix comprises Pb.

4. The article of manufacture of any one of the preceding claims, wherein the matrix comprises at least one composition selected from PbTe and PbSe.

5. The article of manufacture of any one of the preceding claims, wherein the nanoinclusions comprise Ag or Cu.

6. The article of manufacture of any one of the preceding claims, wherein the nanoinclusions comprise at least one composition selected from Ag₂Te and Ag₂Se.

7. The article of manufacture of any one of the preceding claims further comprising a dopant.

8. The article of manufacture of claim 7 comprising at least one dopant selected from La and Na.

9. The article of manufacture of any one of the preceding claims, wherein at least one dimension of the nanoinclusions is larger than 200 nanometers.

10. A method of manufacturing an article comprising:
heating a first material comprising at least a first element and a second material comprising at least a second element to form a mixture;
cooling the mixture to precipitate nanoinclusions comprising the second element; and annealing the mixture.

11. The method of claim 10, wherein the first element of the first material comprises Pb.

12. The method of claim 10 or claim 11, wherein the first material further comprises at least one composition selected from Te and Se.

13. The method of any one of claims 10-12, wherein the second element of the nanoinclusions comprises Ag or Cu.

14. The method of claim 13, wherein the nanoinclusions further comprise at least one composition selected from Te and Se.

15. The method of any one of claims 10-14 further comprising repeating the cooling.

16. The method of any one of claims 10-15 further comprising repeating the annealing.

17. The method of any one of claims 10-16 further comprising doping the article with a dopant.

18. The method of claim 17, wherein the dopant comprises at least one dopant selected from La and Na.

19. A method of using an article of manufacture in a thermoelectric device, wherein the article of manufacture comprises a matrix and nanoinclusions, wherein the nanoinclusions are dispersed in the matrix, and wherein the article of manufacture has a thermoelectric figure of merit (zT) of at least 1.

20. The method of claim 19 comprising
applying a temperature gradient to the article of manufacture; and
collecting electrical energy.

21. The method of claim 19 comprising
applying electrical energy to the article of manufacture; and
transferring heat from a first space at a first operation temperature to a second space at a second operation temperature, wherein the first operation temperature is lower than the second operation temperature.
